(19) United States
(12) Patent Application Publication
(10) Pub. No.: US 2012/0012176 A1
(43) Pub. Date: Jan. 19, 2012

(54) SOLAR CELL AND METHOD OF MANUFACTURING THE SAME

(76) Inventors: Young-Jin Kim, Yongin-si (KR); Dong-Seop Kim, Seongnam-si (KR); Doo-Youl Lee, Seoul (KR); Jun-Hyun Park, Suwon-si (KR); Sang-Ho Kim, Seoul (KR); Ju-Hyun Jeong, Yongin-si (KR); Young-Soo Kim, Seoul (KR); Chan-Bin Mo, Hwaseong-si (KR); Young-Su Kim, Seoul (KR); Myeong-Woo Kim, Seoul (KR); Sang-Joon Lee, Seoul (KR)

(21) Appl. No.: 13/107,310

(22) Filed: May 13, 2011

(30) Foreign Application Priority Data
Jul. 19, 2010 (KR) 2010-0069419

(51) Int. Cl. H01L 31/0216; H01L 31/18

(52) U.S. Cl. 136/256; 438/98; 257/E31.124

(57) ABSTRACT

A solar cell includes a substrate, a doped pattern, a contact layer, and an electrode. The substrate includes a first surface onto which sunlight is incident and a second surface facing the first surface. The doped pattern is formed on the second surface of the substrate and the contact layer is formed on the doped pattern. The electrode is formed on the contact layer and is electrically connected to the doped pattern. Accordingly, a contact resistance between the substrate and the electrode may be decreased, so that the doped pattern and the electrode may be uniformly formed and a power efficiency of the solar cell may be improved.

### CROSS-REFERENCE TO RELATED APPLICATION

This application claims priority under 35 U.S.C. §119 to Korean Patent Application No. 2010-69419, filed on Jul. 19, 2010 in the Korean Intellectual Property Office (KIPO), the contents of which are herein incorporated by reference in their entirety.

### BACKGROUND

1. Technical Field

Exemplary embodiments of the present invention relate to a solar cell and a method of manufacturing the solar cell. More particularly, exemplary embodiments of the present invention relate to a solar cell capable of decreasing a contact resistance between a substrate and an electrode and a method of manufacturing the solar cell.

2. Discussion of the Related Art

Semiconductors may be divided into p-type semiconductors and n-type semiconductors according to impurities implanted into a substrate. The impurities are implanted into a substrate that is made from an element in Group IV, such as silicon (Si) or germanium (Ge), to form a p-type semiconductor or a n-type semiconductor.

A solar cell is an energy conversion element converting sunlight into electricity using a photovoltaic effect. When sunlight is incident onto a substrate of the solar cell, electrons and holes are generated inside of the solar cell. The electrons and the holes respectively move to positive and negative poles of the solar cell, so that a photo-electromotive force is generated. The photo-electromotive force is caused by a potential difference between the positive and negative poles. Thus, when the solar cell is connected to a load, an electric current flows across the load.

The positive electrode or the negative electrode may be formed on a surface opposite to an incident surface onto which sunlight is incident. The positive and negative electrodes may be formed by a screen printing method.

However, in a process for forming the positive and negative electrodes, a non-uniformity of the substrate, a viscosity of a metal paste, a defect of a stencil, etc., may cause a loose contact between the electrodes and the substrate. Such loose contact may increase contact resistance and resultantly decrease power efficiency of the solar cell.

### SUMMARY

Exemplary embodiments of the present invention provide a solar cell capable of decreasing a contact resistance between a substrate and an electrode.

Exemplary embodiments of the present invention also provide a method of manufacturing the solar cell.

According to an embodiment of the present invention, a solar cell includes a substrate, a doped pattern, a contact layer and an electrode. The substrate includes a first surface onto which sunlight is incident and a second surface facing the first surface. The doped pattern is formed on the second surface of the substrate, and the contact layer is formed on the doped pattern. The electrode is formed on the contact layer and is electrically connected to the doped pattern.

According to an exemplary embodiment, the contact layer may include at least one of silicon-germanium (SiGe) doped with a dopant and silicon (Si) doped with the dopant. The dopant may include at least one selected from the group consisting of boron (B), aluminum (Al), gallium (Ga), indium (In), phosphorus (P), and arsenic (As).

According to an exemplary embodiment, the contact layer may include a first contact layer doped with the dopant of a first concentration, and a second contact layer doped with the dopant of a second concentration lower than the first concentration. The second contact layer may be formed on the first contact layer.

According to an exemplary embodiment, the contact layer may include at least one selected from the group consisting of titanium (Ti), aluminum (Al), titanium tungsten (TiW), tungsten silicide, tungsten nitride, titanium nitride, aluminum nitride, and tantalum nitride.

According to an exemplary embodiment, the doped pattern may be formed on a portion of the second surface, and the solar cell may further include an insulating layer that may expose the doped pattern and may be formed on the second surface.

According to an exemplary embodiment, the contact layer may be formed between the doped pattern and the electrode, and between the insulating layer and the electrode. Alternatively, the contact layer may be formed only between the doped pattern and the electrode.

According to an exemplary embodiment, the solar cell may further include a passivation layer between the second surface of the substrate and the insulating layer. The passivation layer may include aluminum oxide (Al₂O₃).

According to an exemplary embodiment, the doped pattern may include a first doped pattern doped with a first dopant, and a second doped pattern doped with a second dopant.

According to an exemplary embodiment, the contact layer may be formed between the first doped pattern and the electrode, between the second doped pattern and the electrode, and between the insulating layer and the electrode. Alternatively, the contact layer may be formed between the first doped pattern and the electrode, and between the second doped pattern and the electrode. Alternatively, the contact layer may be formed only between the first doped pattern and the electrode.

According to an exemplary embodiment, the doped pattern may be entirely formed on the second surface, and the contact layer may be entirely formed on the doped pattern.

According to an exemplary embodiment, the electrode may include at least one selected from the group consisting of aluminum (Al), silver (Ag), titanium (Ti), copper (Cu), tungsten (W), tin (Sn), and titanium nitride.

According to an embodiment of the present invention, a method of manufacturing a solar cell is provided as follows. A contact layer is formed on a second surface of a substrate. The substrate includes a first surface onto which sunlight is incident and the second surface facing the first surface. A conductive metal layer is formed on the contact layer. The conductive metal layer is fired to form a doped pattern on the second surface of the substrate and to form an electrode on the contact layer.

According to an exemplary embodiment, the contact layer may include at least one of silicon-germanium (SiGe) doped with a dopant and silicon (Si) doped with the dopant. The dopant may include at least one selected from the group consisting of boron (B), aluminum (Al), gallium (Ga), indium (In), phosphorus (P), and arsenic (As).

According to an exemplary embodiment, the contact layer may include at least one selected from the group consisting of titanium (Ti), aluminum (Al), titanium tungsten (TiW), tungsten silicide, tungsten nitride, titanium nitride, aluminum nitride, and tantalum nitride.

According to an exemplary embodiment, the contact layer may be formed by injecting a boron trichloride (BCl₃) gas, a germane (GeH₄) gas, and a silane (SiH₄) gas.

According to an exemplary embodiment, the contact layer may be formed by injecting a first gas composition having a boron trichloride (BCl₃) gas of a first concentration, a germane (GeH₄) gas, and a silane (SiH₄) gas, and injecting a second gas composition having a boron trichloride (BCl₃) gas of a second concentration lower than the first concentration, a germane (GeH₄) gas, and a silane (SiH₄) gas.

According to an exemplary embodiment, the second surface of the substrate may be cleaned by injecting a boron trichloride (BCl₃) gas before the contact layer is formed.

According to an exemplary embodiment, the conductive metal layer may include at least one selected from the group consisting of aluminum (Al), silver (Ag), titanium (Ti), copper (Cu), tungsten (W), tin (Sn), and titanium nitride.

According to an exemplary embodiment, the conductive metal layer may be fowled on the contact layer using a screen printing method.

According to an exemplary embodiment, an insulating layer may be further formed on the second surface of the substrate, and the insulating layer may be further patterned to define a diffusion region exposing the second surface.

According to an exemplary embodiment, a passivation layer may be further formed between the second surface of the substrate and the insulating layer.

According to an embodiment of the present invention, a method of manufacturing a solar cell is provided as follows. A first dopant and a second dopant are doped on a second surface of a substrate to form a first doped pattern and a second doped pattern, respectively. The substrate includes a first surface onto which sunlight is incident and the second surface facing the first surface. A contact layer is formed on the first doped pattern. A first electrode and a second electrode electrically connected to the first and second doped patterns, respectively, are formed.

According to an embodiment of the present invention, the solar cell includes the contact layer formed on the doped pattern, so that the contact resistance between the substrate and the electrode may be decreased. Accordingly, the doped pattern and the electrode may be uniformly formed and the power efficiency of the solar cell may be improved.

### BRIEF DESCRIPTION OF THE DRAWINGS

The embodiments of the present invention will become more apparent from detailed exemplary embodiments thereof with reference to the accompanying drawings, in which:

FIG. 1 is a perspective view illustrating a solar cell according to an exemplary embodiment of the present invention;

FIG. 2 is a cross-sectional view taken along a line I-I′ of FIG. 1;

FIGS. 3A to 3K are cross-sectional views illustrating a method of manufacturing the solar cell of FIG. 2;

FIG. 4 is a cross-sectional view illustrating a solar cell according to an exemplary embodiment of the present invention;

FIGS. 5A to 5D are cross-sectional views illustrating a method of manufacturing the solar cell of FIG. 4;

FIG. 6 is a cross-sectional view illustrating a solar cell according to an exemplary embodiment of the present invention;

FIGS. 7A to 7D are cross-sectional views illustrating a method of manufacturing the solar cell of FIG. 6;

FIG. 8 is a cross-sectional view illustrating a solar cell according to an exemplary embodiment of the present invention;

FIG. 9 is a perspective view illustrating a solar cell according to an exemplary embodiment of the present invention;

FIG. 10 is a cross-sectional view taken along a line II-II′ of FIG. 9;

FIGS. 11A to 11G are cross-sectional views illustrating a method of manufacturing the solar cell of FIG. 10;

FIG. 12 is a cross-sectional view illustrating a solar cell according to an exemplary embodiment of the present invention;

FIG. 13 is a cross-sectional view illustrating a solar cell according to an exemplary embodiment of the present invention;

FIG. 14 is a perspective view illustrating a solar cell according to an exemplary embodiment of the present invention; and

FIG. 15 is a cross-sectional view taken along a line III-III′ of FIG. 14.

### DETAILED DESCRIPTION

Hereinafter, exemplary embodiments of the present invention will be described in detail with reference to the accompanying drawings

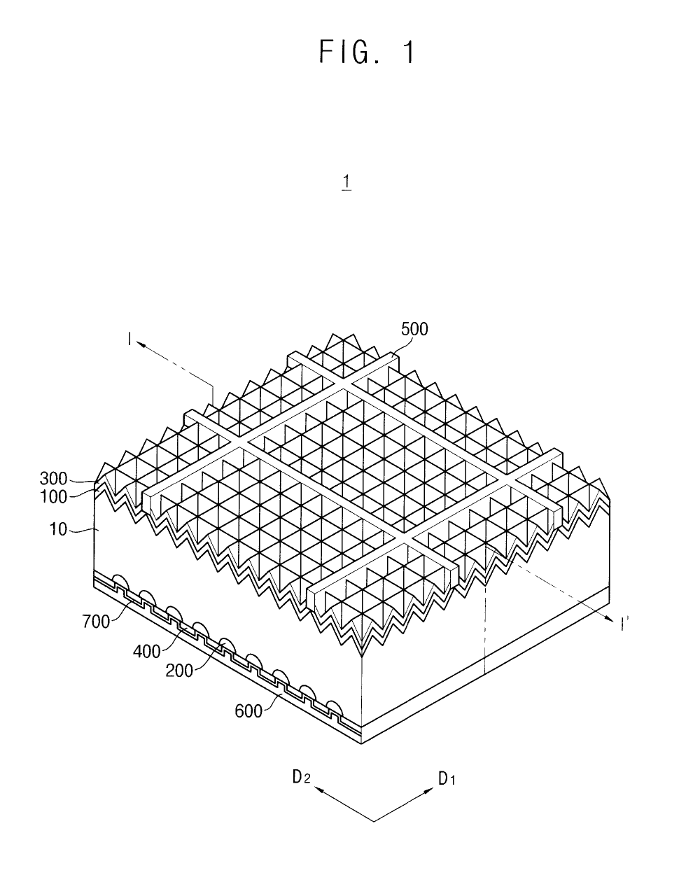

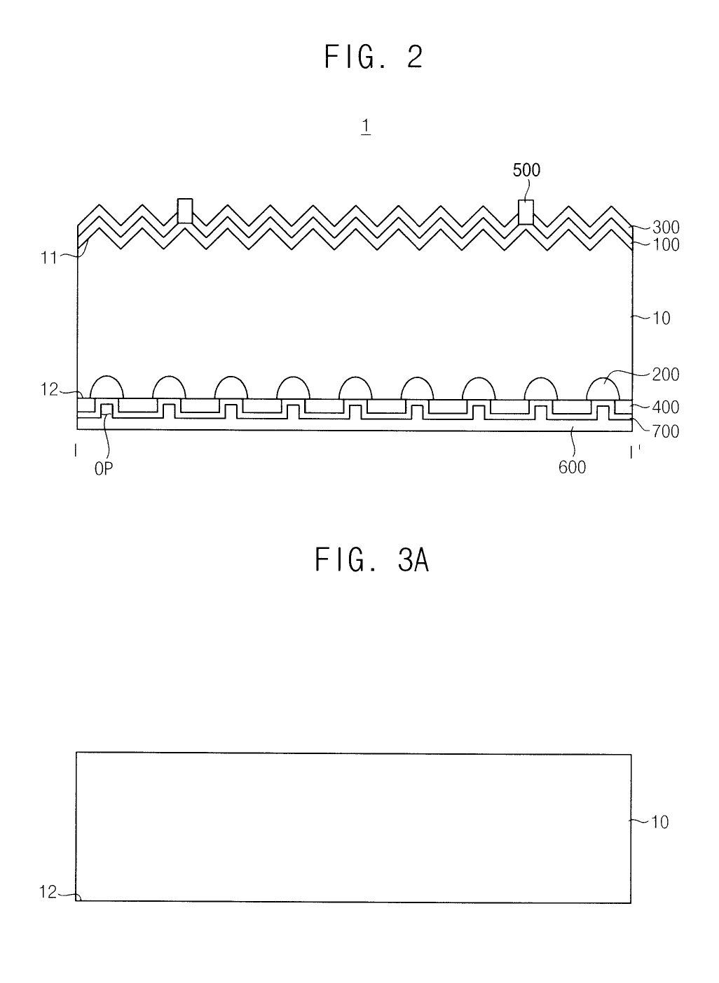

FIG. 1 is a perspective view illustrating a solar cell according to an exemplary embodiment of the present invention. FIG. 2 is a cross-sectional view taken along a line I-I′ of FIG. 1.

Referring to FIGS. 1 and 2, the solar cell 1 according to the present exemplary embodiment includes a base substrate 10 including a doped layer 100 and a doped pattern 200, a first insulating layer 300, a first electrode 500, a second insulating layer 400, a contact layer 700, and a second electrode 600.

The base substrate 10 includes a first surface 11 onto which sunlight is incident and a second surface 12 opposite to the first surface 11. The first surface 11 may include a convex-concave pattern to minimize a reflection of sunlight.

The base substrate 10 may be a p-type silicon substrate. For example, according to an embodiment, the base substrate 10 may include an element in Group IV and an element in Group III. The base substrate 10 may be a single-crystalline substrate, or a polycrystalline substrate. According to an exemplary embodiment, the solar cell 1 includes the p-type silicon substrate. Alternatively, an n-type silicon substrate may be used as the base substrate 10 instead of the p-type silicon substrate.

The doped layer 100 is formed on the first surface 11 of the base substrate 10. The doped layer 100 may include an n-type semiconductor including a first dopant. The first dopant may include an element in Group V, such as phosphorus (P), arsenic (As), etc.

As the doped layer 100 is formed on the base substrate 10, a PN junction of the solar cell 1 is defined. The doped layer 100 substantially receives sunlight and functions as an emitter through which an electric current of the solar cell 1 flows. The doped layer 100 may include a convex-concave pattern in the same manner as the first surface 11. The doped layer 100 may be entirely formed on the first surface 11 of the base substrate 10.

The doped pattern 200 is formed on the second surface 12 of the base substrate 10. The doped pattern 200 may include a p-type semiconductor including a second dopant. The second dopant may include an element in Group III, such as boron (B), aluminum (Al), gallium (Ga), indium (In), etc.

The doped pattern 200 pushes electrons generated by sunlight toward the doped layer 100 in the base substrate 10. The doped pattern 200 pulls holes generated in the base substrate 10 so that the electrons and the holes are not re-coupled.

The doped pattern 200 may be partially formed on the second surface 12 of the base substrate 10. The doped pattern 200 may have a uniform pattern and may have a line shape or a hole shape in a first direction D1. For example, according to an embodiment, the doped pattern 200 may be formed on an area of about 15% of the second surface 12.

The first insulating layer 300 is formed on the doped layer 100. The first insulating layer 300 may be an anti-reflection layer to minimize a reflection of sunlight incident onto the doped layer 100. The first insulating layer 300 may protect the base substrate 10. The first insulating layer 300 may include silicon nitride (SiNx).

The first electrode 500 is directly connected to the doped layer 100 to collect the electrons. The first insulating layer 300 is removed at a portion where the first electrode 500 and the doped layer 100 contact each other. The first electrode 500 may include a conductive metal, such as silver (Ag).

The first electrode 500 may include a plurality of bus lines formed in the first direction D1 and a plurality of finger lines formed in a second direction D2 substantially perpendicular to the first direction D1.

The second insulating layer 400 exposes the doped pattern 200 and is formed on the second surface 12 of the base substrate 10. Openings OP are formed through the second insulating layer 400 to expose the doped pattern 200. The doped pattern 200 is partially formed on the second surface 12, so that the second insulating layer 400 is entirely formed on the second surface 12 except for a portion on which the doped pattern 200 is formed.

The second insulating layer 400 may be a re-reflection layer to re-reflect absorbed sunlight. The second insulating layer 400 may protect the base substrate 10. The second insulating layer 400 may include silicon nitride (SiNx).

The contact layer 700 is formed on the doped pattern 200 and the second insulating layer 400. The contact layer 700 may be entirely formed on the second surface 12 of the base substrate 10 on which the doped pattern 200 and the second insulating layer 400 are formed. For example, according to an embodiment, the contact layer 700 may cover upper and side surfaces of the second insulating layer 400 and the doped pattern 200 exposed by the second insulating layer 400. For example, according to an embodiment, a thickness of the contact layer 700 may be in a range of about 300 nm to about 500 nm.

The contact layer 700 may be a silicon-germanium (SiGe) thin film doped with a dopant or a silicon (Si) thin film doped with the dopant. The silicon-germanium (SiGe) or silicon (Si) thin film may be amorphous, single-crystalline, or polycrystalline film. The dopant may include an element in Group III, such as boron (B), aluminum (Al), gallium (Ga), indium (In), etc. Alternatively, the dopant may include an element in Group V, such as phosphorus (P), arsenic (As), etc.

According to an exemplary embodiment, the doped pattern 200 includes a p-type semiconductor, so that the dopant doped into the contact layer 700 may include the second dopant like the doped pattern 200. For example, according to an embodiment, the contact layer 700 may include silicon-germanium (SiGe) doped with boron (B).

Alternatively, the contact layer 700 may include titanium (Ti), aluminum (Al), titanium tungsten (TiW), tungsten silicide, tungsten nitride, titanium nitride, aluminum nitride, tantalum nitride, etc.

The second electrode 600 is formed on the contact layer 700. The contact layer 700 includes the dopant or a metal element functioning as a conductor, so that the second electrode 600 is electrically connected to the doped pattern 200 through the openings OP.

The second electrode 600 may include a conductive metal, such as aluminum (Al), silver (Ag), titanium (Ti), copper (Cu), tungsten (W), tin (Sn), titanium nitride, etc. For example, according to an embodiment, the second electrode 600 may include aluminum (Al).

The contact layer 700 has a superior adhesive strength with the second electrode 600 including the conductive metal and with the base substrate 10 including the silicon, because the contact layer 700 includes the conductive metal and the silicon. Therefore, a contact resistance between the base substrate 10 including the doped pattern 200 and the second electrode 600 may be decreased. Thus, the doped pattern 200 and the second electrode 600 that are formed on interfaces of the contact layer 700 may be uniformly formed, and a power efficiency of the solar cell 1 may be improved.

A principle of generating power by the solar cell 1 will be briefly described. When sunlight is incident onto the first surface 11, the holes and the electrons are generated in the base substrate 10 due to photons of sunlight.

The holes move toward the doped pattern 200 due to an electric field generated by the PN junction of the base substrate 10 and the doped layer 100. The electrons move toward the doped layer 100 due to the electric field. The electrodes moved to the doped layer 100 are accumulated in the first electrode 500. The holes moved to the doped pattern 200 are accumulated in the second electrode 600.

Due to the electrons and the holes respectively accumulated in the first electrode 500 and the second electrode 600, an electric potential difference is generated between the first electrode 500 and the second electrode 600. Thus, the solar cell 1 may generate electric power by sunlight.

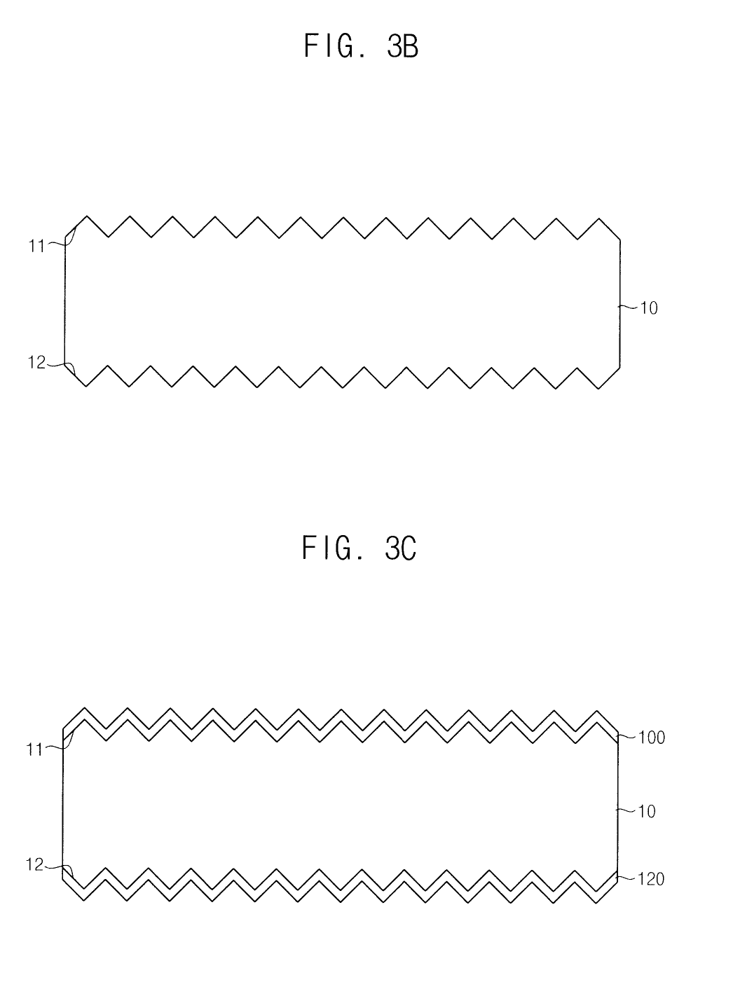

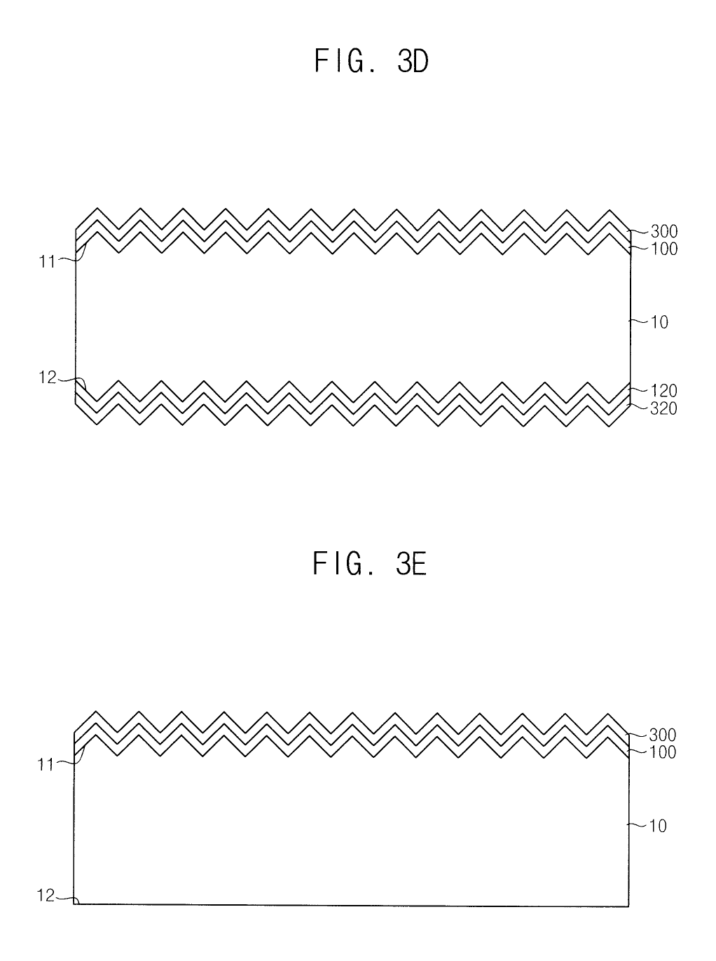

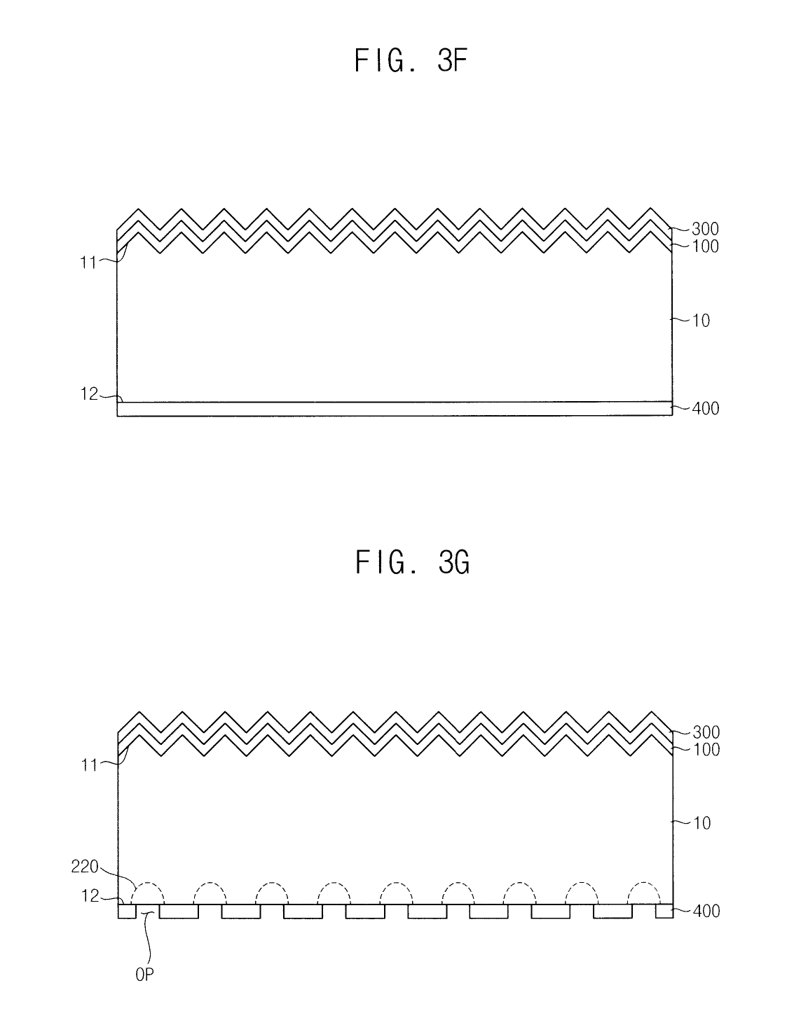

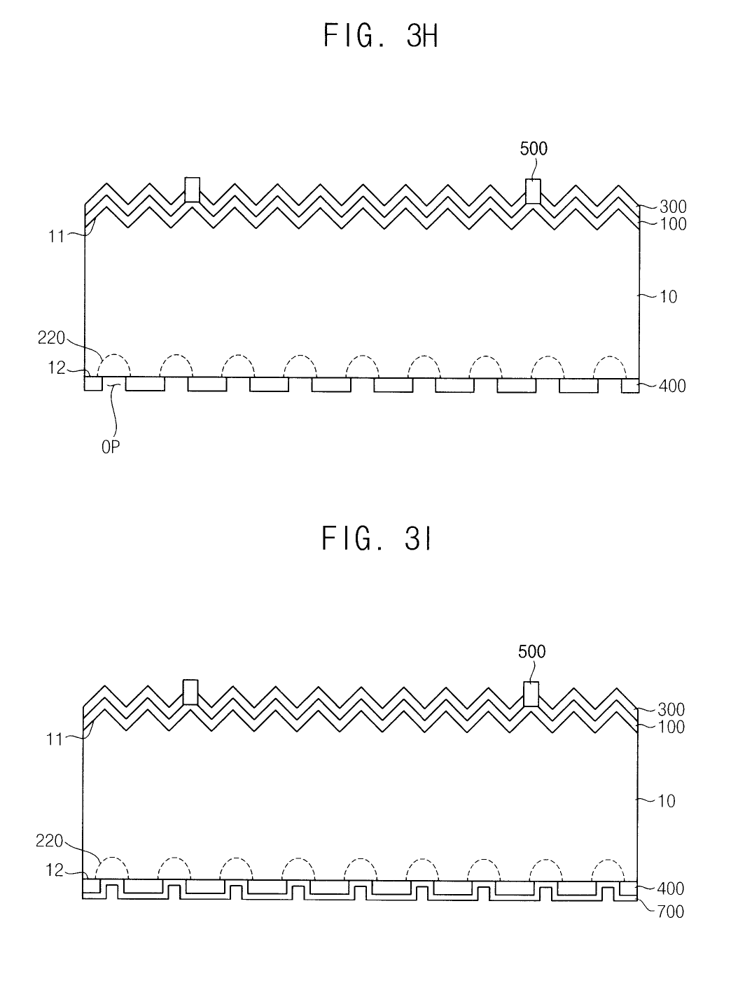

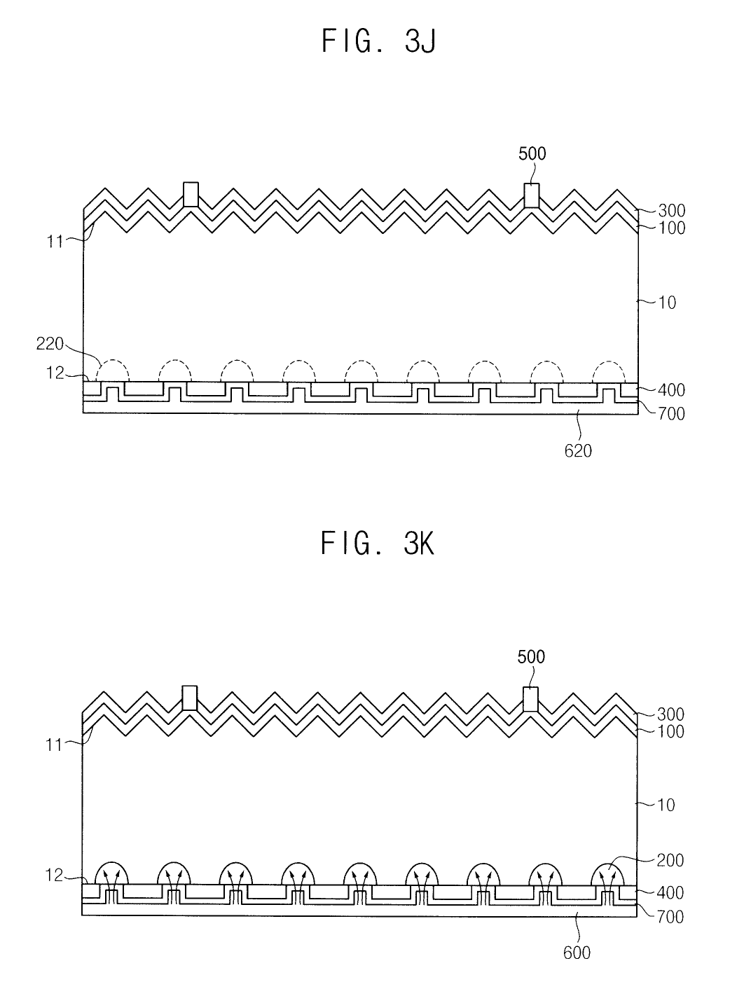

FIGS. 3A to 3K are cross-sectional views illustrating a method of manufacturing the solar cell of FIG. 2.

Referring to FIGS. 2 and 3A, a p-type silicon substrate cut to a predetermined size is prepared for a base substrate 10. A cut surface of the base substrate 10 may be partially etched. Defects generated during a cutting process of the base substrate 10 may be removed through a wet etching process using an alkaline solution or an acid solution.

According to an exemplary embodiment, for convenience of description, a method of manufacturing the solar cell 1 using the p-type silicon substrate will be described. Alternatively, an n-type silicon substrate may be used as the base substrate 10 instead of the p-type silicon substrate.

Referring to FIGS. 2 and 3B, to minimize a reflection of sunlight, a convex-concave pattern is formed on at least one of a first surface 11 and a second surface 12 of the base substrate 10 using an alkaline solution or the like.

According to an exemplary embodiment, the convex-concave pattern is formed on the first surface 11 and the second surface 12 of the base substrate 10. Alternatively, the convex-concave pattern is formed on one of the first and second surfaces 11 and 12 of the base substrate 10.

Referring to FIGS. 2 and 3C, a first dopant is doped on the first and second surfaces 11 and 12 of the base substrate 10 to form doped layers 100 and 120, respectively. The first dopant may include an element in Group V, such as phosphorus (P), arsenic (As), etc.

The doped layers 100 and 120 may formed by conventional doping methods, such as a thermal diffusion method, an ion implantation method, etc.

The doped layer 120 formed on the second surface 12 of the base substrate 10 is removed in a following process.

Referring to FIGS. 2 and 3D, insulating layers 300 and 320, are formed on the doped layers 100 and 120, respectively. The first and second insulating layers 300 and 320 may include silicon nitride (SiNx).

The first and second insulating layers 300 and 320 may be deposited through various deposition processes, such as a chemical vapor deposition (CVD) method, a sputtering method, etc.

The first insulating layer 300 is formed on the first surface 11 and may be an anti-reflection layer to minimize a reflection of sunlight incident onto the doped layer 100. The second insulating layer 320 is formed over the second surface 12 of the base substrate 10 and is removed in a following process.

Referring to FIGS. 2 and 3E, the doped layer 120 and the insulating layer 320 formed on the second surface 12 of the base substrate 10 are removed, and the second surface 12 may be polished to planarize the second surface 12. Alternatively, the doped layer 120 and the insulating layer 320 may not be initially formed on the second surface 12.

Referring to FIGS. 2 and 3F, the second insulating layer 400 is formed on the planarized second surface 12. The second insulating layer 400 may be a re-reflection layer to re-reflect absorbed sunlight. The second insulating layer 400 may protect the base substrate 10. The second insulating layer 400 may include silicon nitride (SiNx).

The second insulating layer 400 may be deposited through various deposition processes, such as a CVD method, a sputtering method, etc.

Referring to FIGS. 2 and 3G, openings OP are formed by partially removing the second insulating layer 400 to expose diffusion regions 220 of the second surface 12. The diffusion regions 220 will be a doped pattern 200 doped with a second dopant in a following process.

For example, according to an embodiment, the second insulating layer 400 may be partially removed using a laser beam. Alternatively, the second insulating layer 400 may be partially removed using a photolithography method.

The second insulating layer 400 may be uniformly patterned according to a shape of the diffusion regions 220, and the openings OP may have a line shape or a hole shape.

Referring to FIGS. 2 and 3H, the first insulating layer 300 is partially removed, and a first electrode 500 is formed on the doped layer 100. The first electrode 500 directly contacts the doped layer 100. The first electrode 500 may include a conductive metal, such as silver (Ag).

The first electrode 500 may be formed by a screen printing method.

According to an exemplary embodiment, the first electrode 500 is formed after the second insulating layer 400 is patterned. Alternatively, the first electrode 500 may be formed before the second insulating layer 400 is patterned, before or after a second electrode 600 is formed in a following process, or simultaneously while the second electrode 600 is formed.

Referring to FIGS. 2 and 3I, a contact layer 700 is formed on the patterned second insulating layer 400. The contact layer 700 covers the second insulating layer 400 and the diffusion regions 220. For example, according to an embodiment, the contact layer 700 may cover upper and side surfaces of the second insulating layer 400 and the doped pattern 200 exposed by the second insulating layer 400. For example, according to an embodiment, a thickness of the contact layer 700 may be in a range of about 300 nm to about 500 nm.

The contact layer 700 may be a silicon-germanium (SiGe) thin film doped with a dopant or a silicon (Si) thin film doped with the dopant. The silicon-germanium (SiGe) or silicon (Si) thin film may be an amorphous, single-crystalline, or polycrystalline film. The dopant may include an element in Group III, such as boron (B), aluminum (Al), gallium (Ga), indium (In), etc. Alternatively, the dopant may include an element in Group V, such as phosphorus (P), arsenic (As), etc.

For example, according to an embodiment, the contact layer 700 may include silicon-germanium (SiGe) doped with boron (B). According to an embodiment, the contact layer 700 may be formed by injecting a boron trichloride (BCl₃) gas, a germane (GeH₄) gas, and a silane (SiH₄) gas via a CVD method. A ratio of the boron trichloride (BCl₃) gas to the germane (GeH₄) gas to the silane (SiH₄) gas may be about 1:2 through 10:2 through 10. The gases may be injected and may react at a temperature of about 450° C.

According to an embodiment, the boron trichloride (BCl₃) gas only may be injected to clean the base substrate 10 before the boron trichloride (BCl₃) gas, the germane (GeH₄) gas and the silane (SiH₄) gas are injected. The boron trichloride (BCl₃) gas may remove a native oxide that may be generated on the diffusion regions 220 exposing the second surface 12.

Alternatively, the contact layer 700 may include titanium (Ti), aluminum (Al), titanium tungsten (TiW), tungsten silicide, tungsten nitride, titanium nitride, aluminum nitride, tantalum nitride, etc.

Referring to FIGS. 2 and 3J, a conductive metal layer 620 is formed on the contact layer 700.

The conductive metal layer 620 may be formed by a screen printing method. The contact resistance between the diffusion regions 220 and the conductive metal layer 620 may be decreased due to the contact layer 700, so that the conductive metal layer 620 may be uniformly formed.

The conductive metal layer 620 may include aluminum (Al), silver (Ag), titanium (Ti), copper (Cu), tungsten (W), tin (Sn), titanium nitride, etc. For example, according to an embodiment, the conductive metal layer 620 may include aluminum (Al) and may be in a paste state.

Referring to FIGS. 2 and 3K, the doped pattern 200 and the second electrode 600 are formed by firing the conductive metal layer 620.

The second electrode 600 is formed by firing the conductive metal layer 620. The doped pattern 200 is formed by doping elements, such as aluminum (Al), included in the conductive metal layer 620 into the diffusion regions 220. According to an embodiment, when the contact layer 700 is a silicon-germanium (SiGe) thin film doped with the dopant or a silicon (Si) thin film doped with the dopant, the dopant included in the contact layer 700 may be also doped into the diffusion regions 220.

Accordingly, the solar cell 1 of FIGS. 1 and 2 may be manufactured.

According to an exemplary embodiment, the contact layer 700 covering the diffusion regions 220 of the base substrate 10 is formed. Thus, the contact resistance between the diffusion regions 220 and the conductive metal layer 620 may be decreased, so that the conductive metal layer 620 may be uniformly formed by a printing process of the conductive metal layer 620. The doped pattern 200 and the second electrode 600 formed by firing the conductive metal layer 620 are may be also uniformly formed.

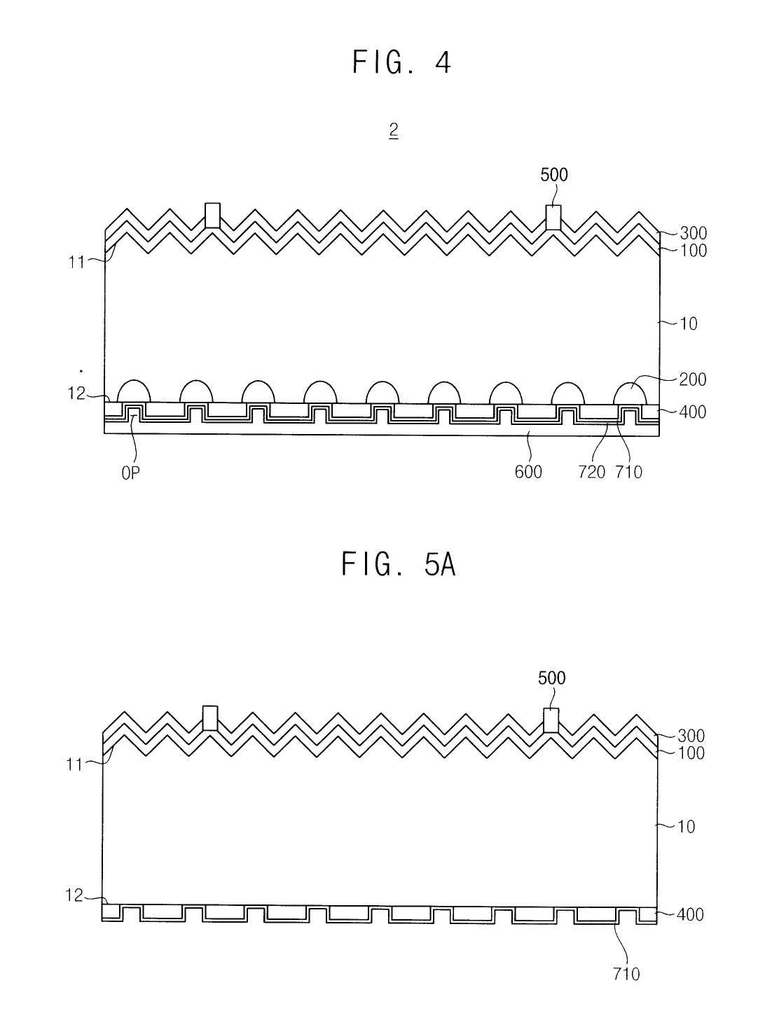

FIG. 4 is a cross-sectional view illustrating a solar cell according to an exemplary embodiment of the present invention.

Referring to FIG. 4, the solar cell 2 according to an exemplary embodiment is substantially the same as the solar cell 1 of FIGS. 1 and 2 except for a first contact layer 710 and a second contact layer 720. Thus, the same reference numerals are used to denote the same or substantially the same elements as those described in connection with FIGS. 1 and 2.

The solar cell 2 according to an exemplary embodiment includes a base substrate 10 including a doped layer 100 and a doped pattern 200, a first insulating layer 300, a first electrode 500, a second insulating layer 400, the first contact layer 710, the second contact layer 720, and a second electrode 600.

The first contact layer 710 is formed on the doped pattern 200 and the second insulating layer 400. The first contact layer 710 may be entirely formed on the second surface 12 of the base substrate 10 on which the doped pattern 200 and the second insulating layer 400 are formed. For example, according to an embodiment, the first contact layer 710 may cover upper and side surfaces of the second insulating layer 400 and the doped pattern 200 exposed by the second insulating layer 400.

The second contact layer 720 may be formed on the first contact layer 710. The second contact layer 720 covers upper and side surfaces of the first contact layer 710. For example, according to an embodiment, a total thickness of the first and second contact layers 710 and 720 may be in a range of about 300 nm to about 500 nm.

The first contact layer 710 and the second contact layer 720 may be a silicon-germanium (SiGe) thin film doped with a dopant or a silicon (Si) thin film doped with the dopant. The first contact layer 710 and the second contact layer 720 may be doped with the dopant having concentrations different from each other. The silicon-germanium (SiGe) or silicon (Si) thin film may be an amorphous, single-crystalline, or polycrystalline film.

The dopant may include an element in Group III, such as boron (B), aluminum (Al), gallium (Ga), indium (In), etc. Alternatively, the dopant may include an element in Group V, such as phosphorus (P), arsenic (As), etc.

According to an exemplary embodiment, the doped pattern 200 includes the p-type semiconductor, so that the dopant doped into the contact layer 700 may include the second dopant like the doped pattern 200. For example, according to an embodiment, the first contact layer 710 and the second contact layer 720 may include silicon-germanium (SiGe) doped with boron (B) of different concentrations, respectively. According to an embodiment, the first contact layer 710 may be doped with boron (B) of a first concentration, and the second contact layer 720 may be doped with boron (B) of a second concentration lower than the first concentration.

According to an exemplary embodiment, the contact layer is a double layer. Alternatively, the contact layer may be a multilayer having more than three layers.

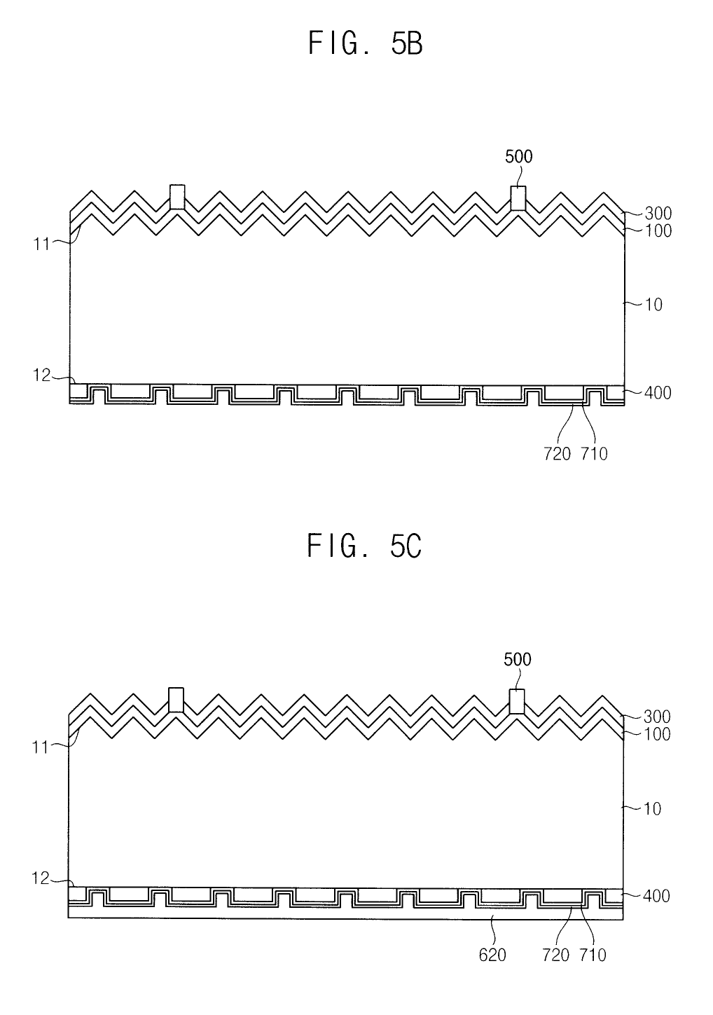

FIGS. 5A to 5D are cross-sectional views illustrating a method of manufacturing the solar cell of FIG. 4.

The method of manufacturing the solar cell 2 according to an exemplary embodiment is substantially the same as the method of manufacturing the solar cell 1 of FIG. 2 except for at least a description of FIGS. 3I to 3K. Thus, the same reference numerals are used to denote the same or substantially the same elements as those described in connection with FIG. 2.

Referring to FIGS. 4, 3A to 3H, and 5A, the first contact layer 710 is formed on the patterned second insulating layer 400. The first contact layer 710 covers the second insulating layer 400 and the diffusion regions 220.

For example, according to an embodiment, the first contact layer 710 may include silicon-germanium (SiGe) doped with boron (B) of a first concentration. According to an embodiment, the first contact layer 710 may be formed by injecting a boron trichloride (BCl₃) gas, a germane (GeH₄) gas, and a silane (SiH₄) gas via a CVD method. The boron trichloride (BCl₃) gas, the germane (GeH₄) gas, and the silane (SiH₄) gas may be injected in amounts of about 100 ml, 1,000 ml, and 1,000 ml, respectively. The gases may be injected and may react at a temperature of about 450° C.

According to an embodiment, the boron trichloride (BCl₃) gas only may be injected to clean the base substrate 10 before the boron trichloride (BCl₃) gas, the germane (GeH₄) gas, and the silane (SiH₄) gas are injected. The boron trichloride (BCl₃) gas may remove a native oxide that may be generated on the diffusion regions 220 exposing the second surface 12.

Referring to FIGS. 4 and 5B, the second contact layer 720 is formed on the first contact layer 710. The second contact layer 720 covers the first contact layer 710.

For example, according to an embodiment, the second contact layer 720 may include silicon-germanium (SiGe) doped with boron (B) of a second concentration. The second concentration may be lower than the first concentration. According to an embodiment, the second contact layer 720 may be formed by injecting a boron trichloride (BCl₃) gas, a germane (GeH₄) gas, and a silane (SiH₄) gas via the CVD method. The boron trichloride (BCl₃) gas, the germane (GeH₄) gas, and the silane (SiH₄) gas may be injected in amounts of about 50 ml, 1,000 ml, and 1,000 ml, respectively. The gases may be injected and may react at a temperature of about 450° C.

Referring to FIGS. 4 and 5C, a conductive metal layer 620 is formed on the second contact layer 720.

The conductive metal layer 620 may be formed by a screen printing method. The contact resistance between the diffusion regions 220 and the conductive metal layer 620 may be decreased due to the first and second contact layers 710 and 720, so that the conductive metal layer 620 may be uniformly formed.

The conductive metal layer 620 may include aluminum (Al), silver (Ag), titanium (Ti), copper (Cu), tungsten (W), tin (Sn), titanium nitride, etc. For example, according to an embodiment, the conductive metal layer 620 may include aluminum (Al) and may be in a paste state.

Referring to FIGS. 4 and 5D, the doped pattern 200 and the second electrode 600 are formed by firing the conductive metal layer 620.

The second electrode 600 is formed by firing the conductive metal layer 620. The doped pattern 200 is formed by doping elements, such as aluminum (Al), included in the conductive metal layer 620 into the diffusion regions 220. According to an embodiment, boron (B) included in the first and second contact layers 710 and 720 may be also doped into the diffusion regions 220.

Accordingly, the solar cell 2 of FIG. 4 may be manufactured.

According to an exemplary embodiment, the first and second contact layers 710 and 720 covering the diffusion regions 220 are formed. Thus, the first contact layer 710 doped at a relatively high concentration may allow the dopant to easily dope into the diffusion regions 220 in a following process. The second contact layer 720 doped at a relatively low concentration may further improve the contact resistance with the second electrode 600 formed in a following process.

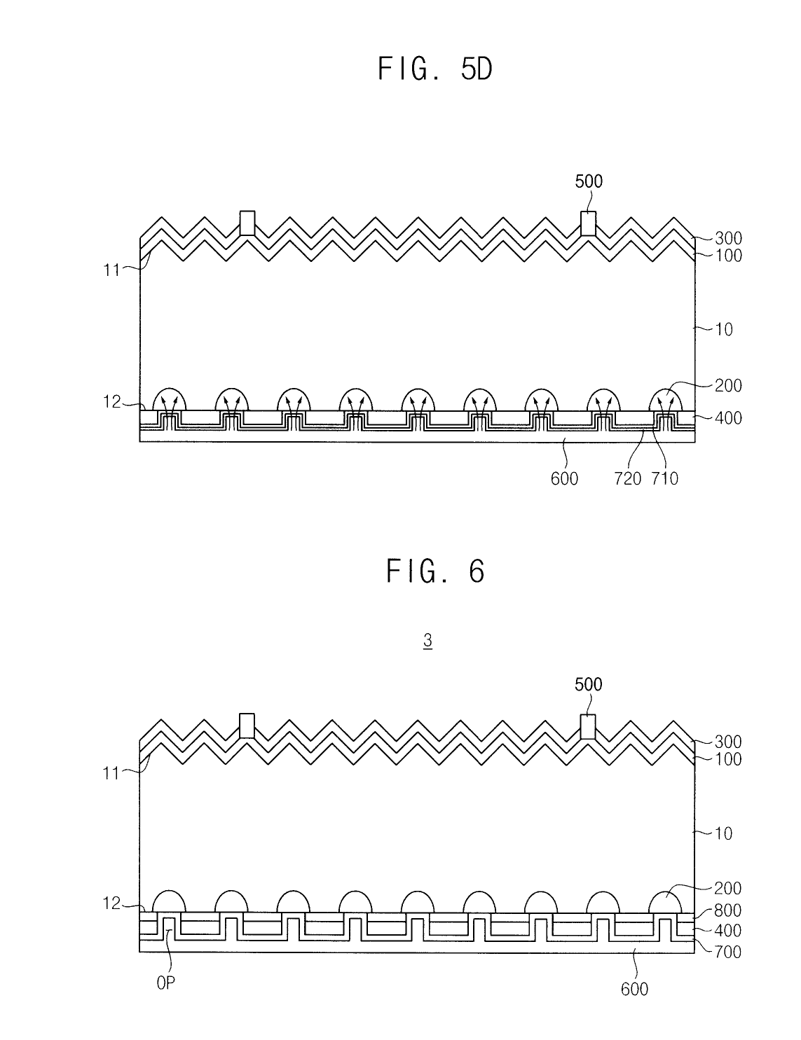

FIG. 6 is a cross-sectional view illustrating a solar cell according to an exemplary embodiment of the present invention.

Referring to FIG. 6, the solar cell 3 according to an exemplary embodiment is substantially the same as the solar cell 1 of FIGS. 1 and 2 except for a passivation layer 800. Thus, the same reference numerals are used to denote the same or substantially the same elements as those described in connection with FIGS. 1 and 2.

The solar cell 3 according to an exemplary embodiment includes a base substrate 10 including a doped layer 100 and a doped pattern 200, a first insulating layer 300, a first electrode 500, the passivation layer 800, a second insulating layer 400, a contact layer 700, and a second electrode 600.

The passivation layer 800 is formed between the base substrate 10 and the second insulating layer 400. The passivation layer 800 may have substantially the same shape as the second insulating layer 400. The passivation layer 800 may prevent an approach of electrons and a leakage current. The passivation layer 800 may include aluminum oxide (Al₂O₃).

The contact layer 700 is formed on the doped pattern 200 and the second insulating layer 400. The contact layer 700 may be entirely formed on the second surface 12 of the base substrate 10 on which the doped pattern 200 and the second insulating layer 400 are formed. For example, according to an embodiment, the contact layer 700 covers side surfaces of the passivation layer 800, and upper and side surfaces of the second insulating layer 400 and the doped pattern 200. For example, according to an embodiment, a thickness of the contact layer 700 may be in a range of about 300 nm to about 500 nm.

According to an exemplary embodiment, the passivation layer 800 is formed only on the second surface 12 of the base substrate 10. The passivation layer 800 may be also formed on the first insulating layer 300.

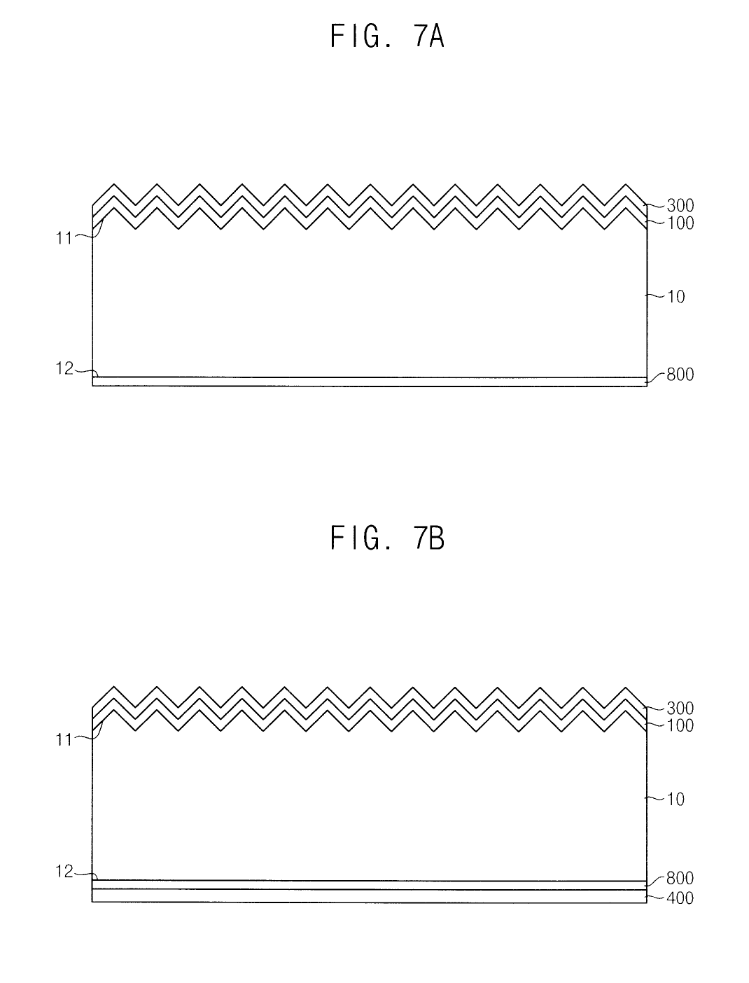

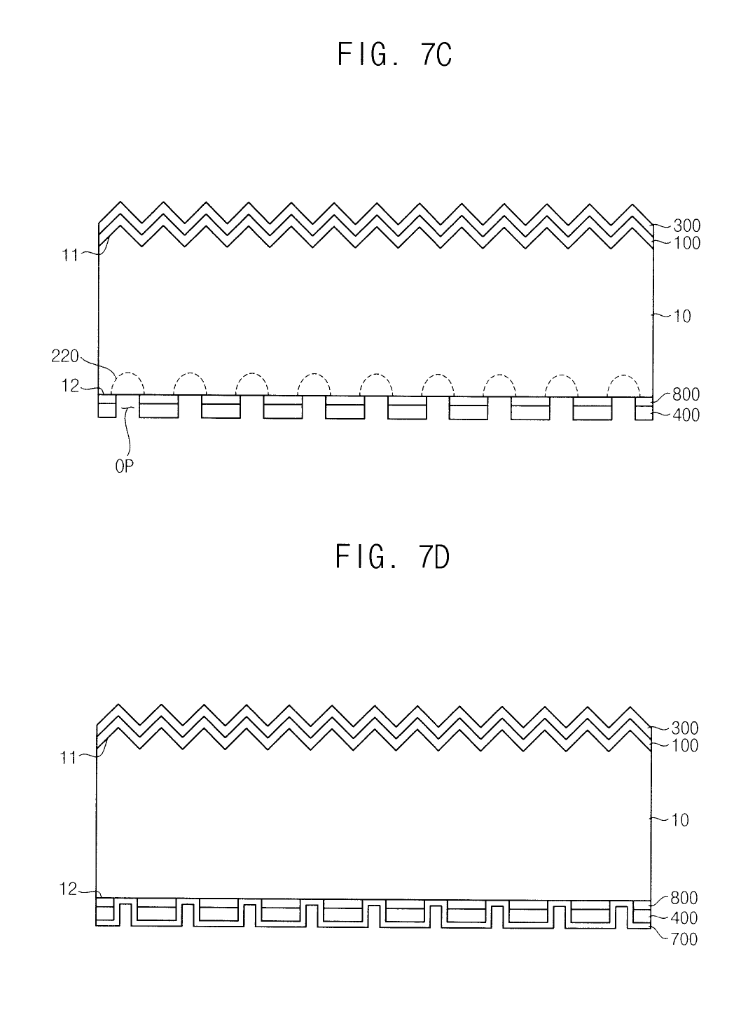

FIGS. 7A to 7D are cross-sectional views illustrating a method of manufacturing the solar cell of FIG. 6.

The method of manufacturing the solar cell 3 according to an exemplary embodiment is substantially the same as the method of manufacturing the solar cell 1 of FIG. 2 except for at least a description of FIGS. 3F to 3I. Thus, the same reference numerals are used to denote the same or substantially the same elements as those described in connection with FIG. 2.

Referring to FIGS. 6, 3A to 3E, and 7A, the passivation layer 800 is formed on the planarized second surface 12. The passivation layer 800 may include aluminum oxide (Al₂O₃).

Although not shown in the figure, the passivation layer 800 may be formed not only on the planarized second surface 12, but also on the first insulating layer 300.

Referring to FIGS. 6 and 7B, the second insulating layer 400 is formed on the passivation layer 800. The second insulating layer 400 may be a re-reflection layer to re-reflect absorbed sunlight. The second insulating layer 400 may protect the base substrate 10. The second insulating layer 400 may include silicon nitride (SiNx).

The second insulating layer 400 may be deposited through various deposition processes, such as a CVD method, a sputtering method, etc.

Referring to FIGS. 6 and 7C, openings OP are formed by partially removing the passivation layer 800 and the second insulating layer 400 to expose diffusion regions 220 of the second surface 12. The diffusion regions 220 become the doped pattern 200 when doped with the second dopant in a following process.

For example, according to an embodiment, the passivation layer 800 and the second insulating layer 400 may be partially removed using a laser beam. Alternatively, the passivation layer 800 and the second insulating layer 400 may be removed using a photolithography method.

The passivation layer 800 and the second insulating layer 400 may have substantially the same shape as each other. The passivation layer 800 and the second insulating layer 400 may be simultaneously patterned.

The passivation layer 800 and the second insulating layer 400 may be uniformly patterned, and the openings OP may have a line shape or a hole shape.

Although not shown in the figure, a first electrode 500 may be formed before or after the passivation layer 800 and the second insulating layer 400 are patterned. Alternatively, the first electrode 500 may be formed before or after a second electrode 600 is formed in a following process, or may be simultaneously formed while the second electrode 600 is formed.

The following processes are substantially the same as the method of manufacturing the solar cell 1 of FIG. 2.

Accordingly, the solar cell 3 of FIG. 6 may be manufactured.

According to an exemplary embodiment, the solar cell 3 further includes the passivation layer 800 formed between the base substrate 10 and the second insulating layer 400, so that the passivation layer 800 may prevent an approach of electrons and a leakage current in the solar cell 3. Thus, a power efficiency of the solar cell 3 may be more improved.

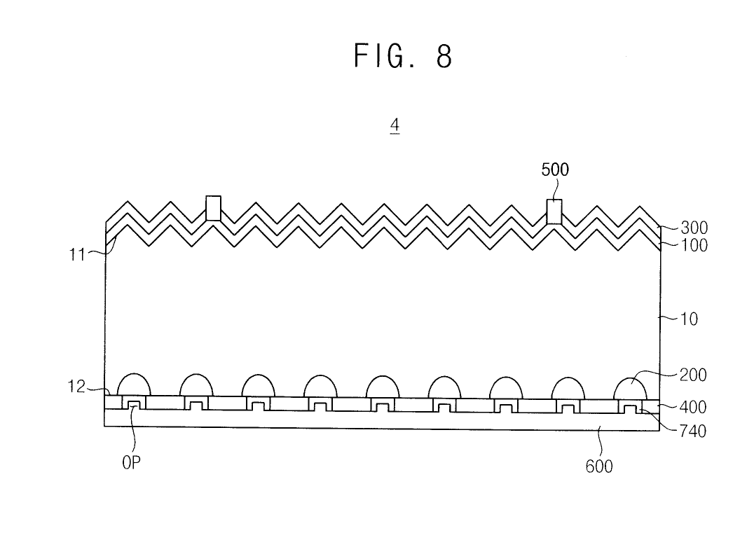

FIG. 8 is a cross-sectional view illustrating a solar cell according to an exemplary embodiment of the present invention.

Referring to FIG. 8, the solar cell 4 according to an exemplary embodiment is substantially the same as the solar cell 1 of FIGS. 1 and 2 except for a contact layer 740. Thus, the same reference numerals are used to denote the same or substantially the same elements as those described in connection with FIGS. 1 and 2.

The solar cell 4 includes a base substrate 10 including a doped layer 100 and a doped pattern 200, a first insulating layer 300, a first electrode 500, a second insulating layer 400, the contact layer 740, and a second electrode 600.

The contact layer 740 is formed around the openings OP. For example, according to an embodiment, the contact layer 740 may be formed between the doped pattern 200 and the second electrode 600, and covers side surfaces of the second insulating layer 400 and the doped pattern 200 exposed by the second insulating layer 400.

Although not shown in the figure, the contact layer 740 may have two or more layers. The solar cell 4 further includes a passivation layer formed between the base substrate 10 and the second insulating layer 400.

The method of manufacturing the solar cell 4 according to an exemplary embodiment is substantially the same as the method of manufacturing the solar cell 1 of FIG. 2, except that the contact layer 740 may be formed only around the openings OP. Alternatively, after the contact layer 700 is formed as shown in FIG. 31, the contact layer 740 may be formed by removing portions of the contact layer 700 except for a portion surrounding the openings OP.

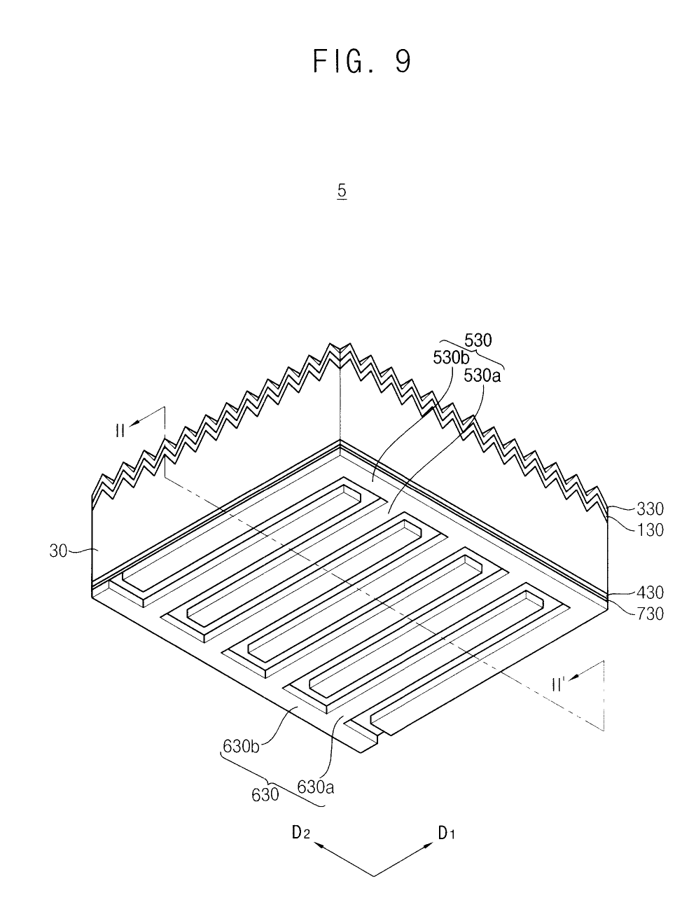

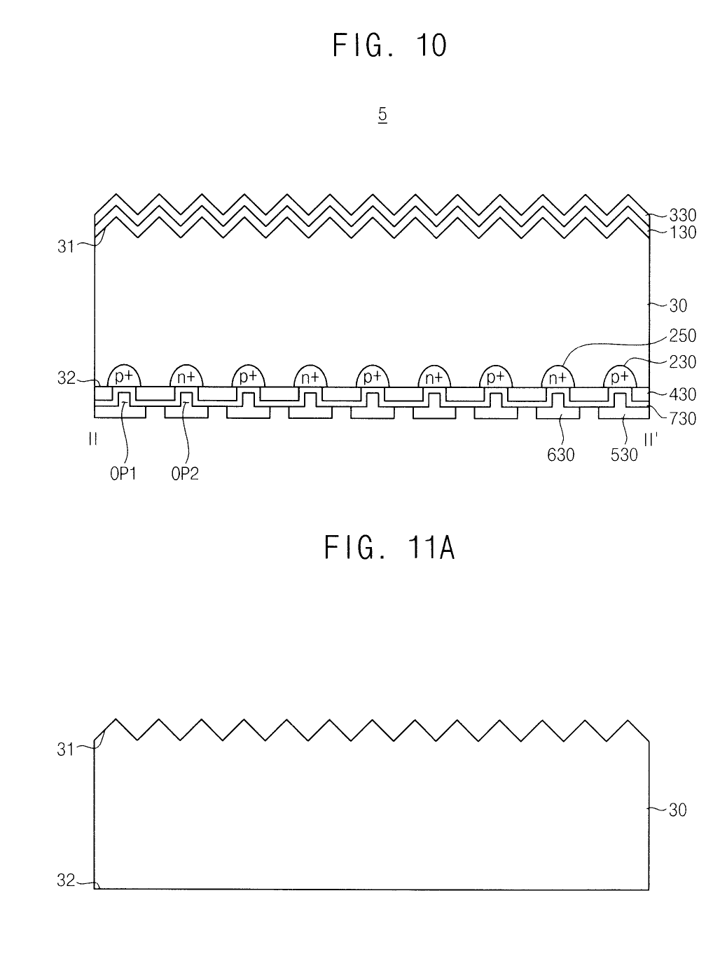

FIG. 9 is a perspective view illustrating a solar cell according to an exemplary embodiment of the present invention. FIG. 10 is a cross-sectional view taken along a line II-II′ of FIG. 9.

Referring to FIGS. 9 and 10, the solar cell 5 according to an exemplary embodiment includes a base substrate 30 including a doped layer 130, a first doped pattern 230, and a second doped pattern 250, a first insulating layer 330, a second insulating layer 430, a contact layer 730, a first electrode 530, and a second electrode 630. The first electrode 530 is electrically connected to the first doped pattern 230 and the second electrode 630 is electrically connected to the second doped pattern 250.

The base substrate 30 includes a first surface 31 onto which sunlight is incident and a second surface 32 facing the first surface 31. The first surface 31 may include a convex-concave pattern to minimize a reflection of sunlight.

The base substrate 30 may be a p-type silicon substrate or an n-type silicon substrate. The base substrate 30 may be single-crystalline, or polycrystalline substrate. According to an exemplary embodiment, it is described that the base substrate 30 is the n-type silicon substrate including an element in Group IV and an element in Group V.

The doped layer 130 is formed on the first surface 31 of the base substrate 30. The doped layer 130 may include an n-type semiconductor including a first dopant. The first dopant may include an element in Group V, such as phosphorus (P), arsenic (As), etc.

The first insulating layer 330 is formed on the doped layer 130. The first insulating layer 330 may be an anti-reflection layer to minimize a reflection of sunlight incident onto the doped layer 130. The first insulating layer 330 may protect the base substrate 30. The first insulating layer 330 may include silicon nitride (SiNx).

The first doped pattern 230 and the second doped pattern 250 are formed on the second surface 32 of the base substrate 30. The first doped pattern 230 and the second doped pattern 250 may be a P⁺ area and an N⁺ area, respectively.

The first doped pattern 230 and the second doped pattern 250 may have a line shape or a hole shape in a first direction D1. The first doped pattern 230 and the second doped pattern 250 may be formed in an alternating manner along a second direction D2 substantially perpendicular to the first direction D1.

The first doped pattern 230 may include the p-type semiconductor (i.e., a p⁺ semiconductor) including a second dopant. The second dopant may include an element in Group III, such as boron (B), aluminum (Al), etc. The first doped pattern 230 may be an emitter layer having a conductive type opposite to that of the base substrate 30. As the first doped pattern 230 is formed, a PN junction of the solar cell 5 is formed.

The second doped pattern 250 may include the n-type semiconductor including the first dopant like the doped layer 130. The second doped pattern 250 may include the n-type semiconductor (i.e., an n⁺ semiconductor) which is doped with the first dopant of a higher concentration than the doped layer 130. For example, according to an embodiment, a concentration of the first dopant of the second doped pattern 250 may be higher than that of the first dopant of the doped layer 130, so that the doped layer 130 may push electrons generated by sunlight toward the second doped pattern 250 in the base substrate 30.

The second insulating layer 430 exposes the first and second doped patterns 230 and 250 and is formed on the second surface 32 of the base substrate 30. First and second openings OP1 and OP2 are formed through the second insulating layer 430 to expose the first and second doped patterns 230 and 250, respectively.

The second insulating layer 430 may be a re-reflection layer to re-reflect absorbed sunlight. The second insulating layer 430 may protect the base substrate 30. The second insulating layer 430 may include silicon nitride (SiNx).

The contact layer 730 is formed on the first and second doped patterns 230 and 250 and the second insulating layer 430. The contact layer 730 may be entirely formed on the second surface 32 of the base substrate 30 on which the first and second doped patterns 230 and 250 and the second insulating layer 430 are formed. For example, according to an embodiment, the contact layer 730 covers upper and side surfaces of the second insulating layer 430 and the first and second doped patterns 230 and 250 exposed by the second insulating layer 430. For example, according to an embodiment, a thickness of the contact layer 730 may be in a range of about 300 nm to about 500 nm.

The contact layer 730 may be a silicon-germanium (SiGe) thin film doped with a dopant or a silicon (Si) thin film doped with the dopant. The silicon-germanium (SiGe) or silicon (Si) thin film may be an amorphous, single-crystalline, or polycrystalline film. The dopant may include an element in Group III, such as boron (B), aluminum (Al), gallium (Ga), indium (In), etc. Alternatively, the dopant may include an element in Group V, such as phosphorus (P), arsenic (As), etc.

Alternatively, the contact layer 730 may include titanium (Ti), aluminum (Al), titanium tungsten (TiW), tungsten silicide, tungsten nitride, titanium nitride, aluminum nitride, tantalum nitride, etc.

The contact layer 730 includes the dopant or a metal element functioning as a conductor, so that the first and second electrodes 530 and 630 are electrically connected to the first and second doped patterns 230 and 250, respectively.

Although not shown in the figure, the contact layer 730 may have two or more layers. According to an embodiment, the solar cell 5 may further include a passivation layer formed between the base substrate 30 and the second insulating layer 430. The passivation layer may have substantially the same shape as the second insulating layer 430 and may prevent an approach of electrons and a leakage current. The passivation layer may include aluminum oxide (Al₂O₃). The passivation layer may be also formed on the first insulating layer 330.

The solar cell 5 has both of the first electrode 530 and the second electrode 630 formed on the second surface 32 of the base substrate 30 differently from the solar cell 1 of FIG. 1. Thus, sunlight is not blocked by the electrode formed on the first surface onto which sunlight is incident, so that a power efficiency of the solar cell 5 may be more improved.

The first electrode 530 and the second electrode 630 are spaced apart from each other. The first electrode 530 and the second electrode 630 are formed in an alternating manner along the second direction D2.

The first electrode 530 is electrically connected to the first doped patterns 230 through the first openings OP1 formed through the second insulating layer 430. The first electrode 530 includes first electrode lines 530a extending in the first direction D1 along the first doped patterns 230 and a first electrode connecting part 530b extending in the second direction D2 and connecting the first electrode lines 530a.

The second electrode 630 is electrically connected to the second doped pattern 250 through the second openings OP2 formed through the second insulating layer 430. The second electrode 630 includes second electrode lines 630a extending in the first direction D1 along the second doped patterns 250 and a second electrode connecting part 630b extending in the second direction D2 and connecting the second electrode lines 630a.

The contact layer 730 may decrease a contact resistance between the base substrate 30 including the first and second doped patterns 230 and 250 and the first and second electrodes 530 and 630. Thus, the first and second electrodes 530 and 630 may be uniformly formed and a power efficiency of the solar cell 5 may be improved.

A principle of generating power by the solar cell 5 will be explained. When sunlight is incident onto the first surface 31, holes and electrons are generated in the base substrate 30 due to photons of sunlight.

The holes move toward the first doped pattern 230 due to an electric field generated by the PN junction of the base substrate 30 and the first doped pattern 230. The electrons move toward the second doped layer 250 due to the electric field. The holes moved to the first doped pattern 230 are accumulated in the first electrode 530. The electrodes moved to the second doped layer 250 are accumulated in the second electrode 630.

Due to the electrons and the holes respectively accumulated in the first electrode 530 and the second electrode 630, an electric potential difference is generated between the first electrode 530 and the second electrode 630. Thus, the solar cell 5 may generate electric power by sunlight.

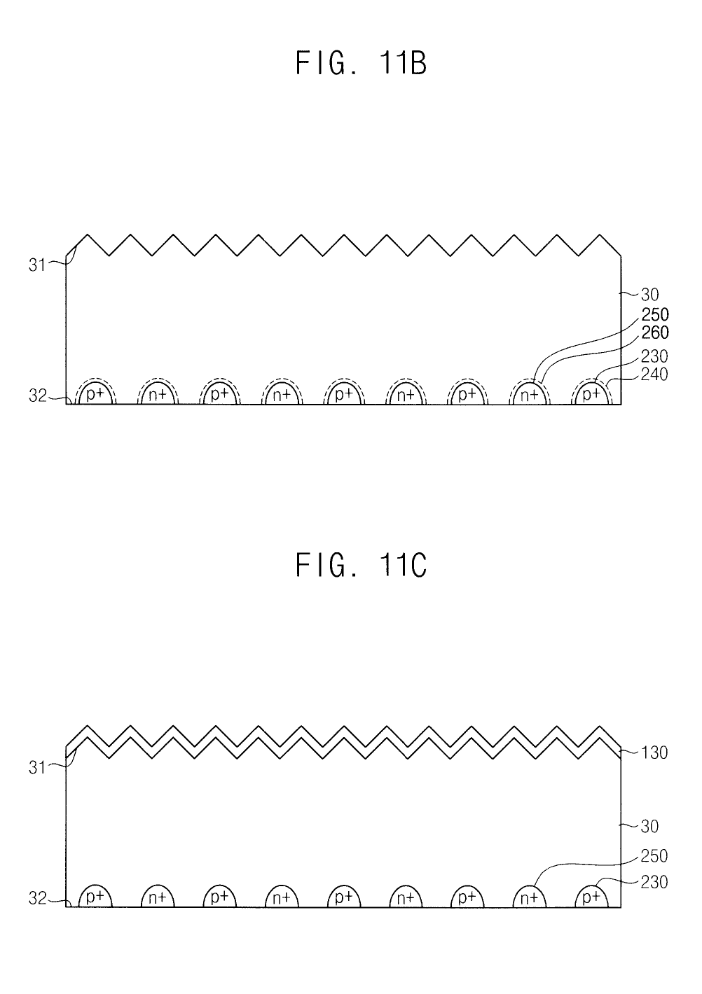

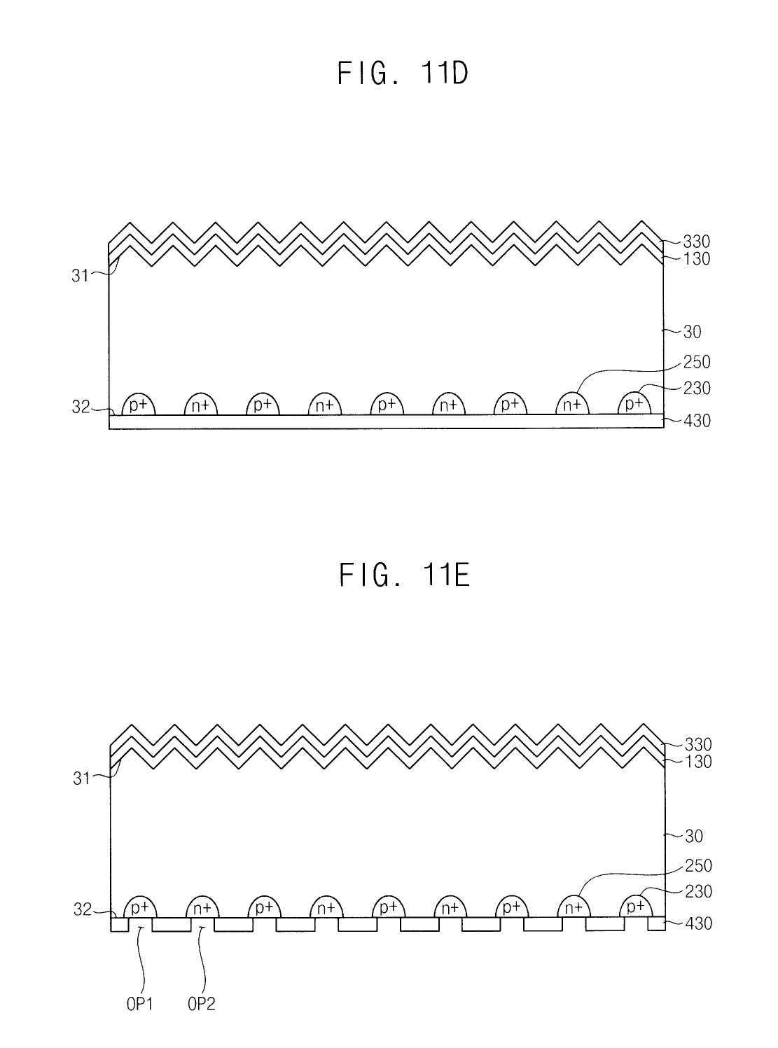

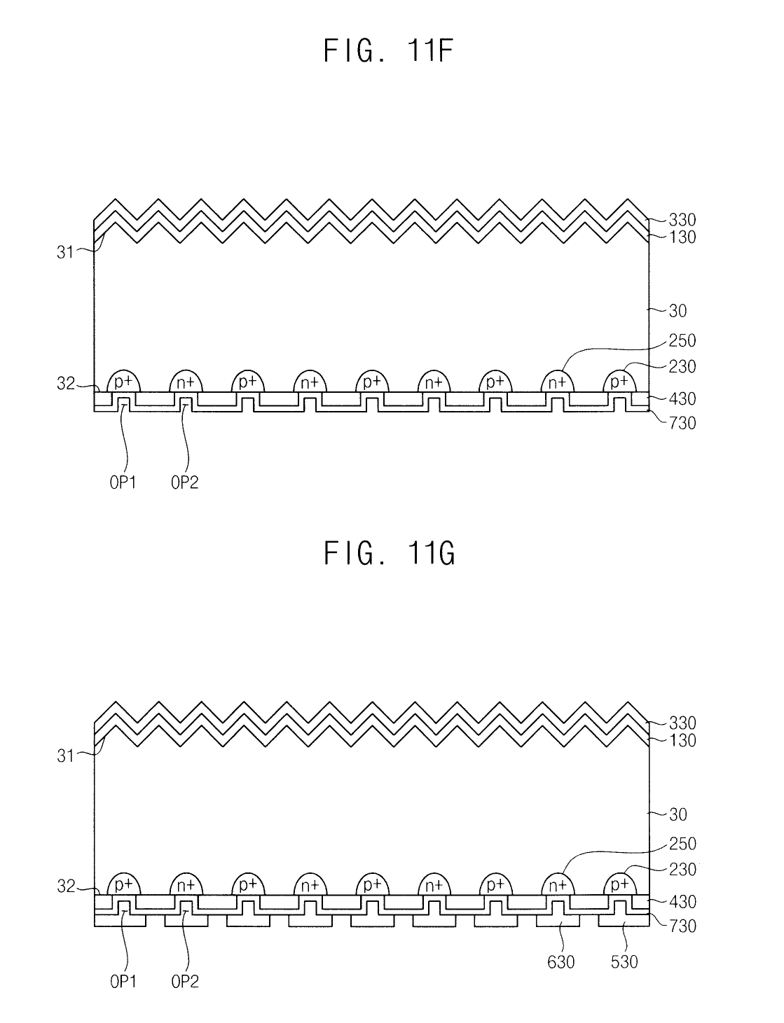

FIGS. 11A to 11G are cross-sectional views illustrating a method of manufacturing the solar cell of FIG. 10.

Referring to FIGS. 10 and 11A, an n-type silicon substrate cut to a predetermined size is prepared for a base substrate 30. A cut surface of the base substrate 30 may be partially etched. Defects generated during a cutting process of the base substrate 30 may be removed through a wet etching process using an alkaline solution or an acid solution.

According to an exemplary embodiment, for convenience of description, a method of manufacturing the solar cell 5 using the n-type silicon substrate will be described. Alternatively, a p-type silicon substrate may be used as the base substrate 30 instead of the n-type silicon substrate.

Then, to minimize a reflection of sunlight, a convex-concave pattern is formed on at least one of a first surface 31 and a second surface 32 of the base substrate 30 using an alkaline solution or the like. The second surface 32 may be polished to planarize the second surface 32 opposite to the first surface 31 onto which sunlight is incident.

Referring to FIGS. 10 and 11B, the second dopant and the first dopant are doped on a first diffusion region 240 and a second diffusion region 260, respectively, which are part of the second surface 32. Accordingly, a first doped pattern 230 doped with the second dopant and a second doped pattern 250 doped with the first dopant are formed.

The first and second dopants may be doped by conventional doping methods, such as a thermal diffusion method, an ion implantation method, etc. A diffusion protective pattern (not shown) may be used to prevent the second dopant from being doped to an outside of the first diffusion region 240 and to prevent the first dopant from being doped to an outside of the second diffusion region 260.

According to an exemplary embodiment, the convex-concave pattern is formed on the base substrate 30 and then the first and second doped patterns 230 and 250 are formed. Alternatively, the first and second doped patterns 230 and 250 may be formed, and then the convex-concave pattern may be formed on the base substrate 30.

Referring to FIGS. 10 and 11C, a doped layer 130 is formed by doping the first dopant on the first surface 31 of the base substrate 30 on which the convex-concave pattern is formed. The first dopant may include an element in Group V, such as phosphorus (P), arsenic (As), etc.

Referring to FIGS. 10 and 11D, a first insulating layer 330 is formed on the first surface 31 on which the doped layer 130 is formed, and a second insulating layer 430 is formed on the second surface 32 on which the first and second doped patterns 230 and 250 are formed.

The first insulating layer 330 may be an anti-reflection layer to minimize a reflection of sunlight incident onto the doped layer 130. The second insulating layer 430 may be a re-reflection layer to re-reflect absorbed sunlight. The first and second insulating layers 330 and 430 may protect the base substrate 30. The first and second insulating layers 330 and 430 may include silicon nitride (SiNx).

The first and second insulating layers 330 and 430 may be deposited through various deposition processes, such as a CVD method, a sputtering method, etc.

According to an exemplary embodiment, the first and second insulating layers 330 and 430 are simultaneously formed. Alternatively, the second insulating layer 430 formed on the second surface 32 may be formed before or after the first insulating layers 330 is formed on the first surface 31.

Referring to FIGS. 10 and 11E, first openings OP1 and second openings OP2 are formed by partially removing the second insulating layer 430 to expose the first and second doped patterns 230 and 250, respectively.

For example, according to an embodiment, the second insulating layer 430 may be partially removed using a laser beam. Alternatively, the second insulating layer 430 may be removed using a photolithography method.

The second insulating layer 430 may be uniformly patterned, and the first and second openings OP1 and OP2 may have a line shape or a hole shape.

Referring to FIGS. 10 and 11F, a contact layer 730 is formed on the patterned second insulating layer 430. The contact layer 730 covers the second insulating layer 430 and the first and second doped patterns 230 and 250. For example, according to an embodiment, the contact layer 730 may cover upper and side surfaces of the second insulating layer 430 and the first and second doped patterns 230 and 250 exposed by the second insulating layer 430. For example, according to an embodiment, a thickness of the contact layer 730 may be in a range of about 300 nm to about 500 nm.

The contact layer 730 may be a silicon-germanium (SiGe) thin film doped with a dopant or a silicon (Si) thin film doped with the dopant. The silicon-germanium (SiGe) or silicon (Si) thin film may be an amorphous, single-crystalline, or polycrystalline film. The dopant may include an element in Group III, such as boron (B), aluminum (Al), gallium (Ga), indium (In), etc. Alternatively, the dopant may include an element in Group V, such as phosphorus (P), arsenic (As), etc.

Alternatively, the contact layer 730 may include titanium (Ti), aluminum (Al), titanium tungsten (TiW), tungsten silicide, tungsten nitride, titanium nitride, aluminum nitride, tantalum nitride, etc.

Referring to FIGS. 10 and 11G, a first electrode 530 electrically connected to the first doped pattern 230 and a second electrode 630 electrically connected to the second doped pattern 250 are formed on the contact layer 730.

The first electrode 530 and the second electrode 630 are spaced apart from each other. The first and second electrodes 530 and 630 may include a conductive metal, such as aluminum (Al), silver (Ag), titanium (Ti), copper (Cu), tungsten (W), tin (Sn), titanium nitride, etc.

The first and second electrodes 530 and 630 may be formed by a screen printing method. The contact resistances between the first and second doped patterns 230 and 250 and the first and second electrodes 530 and 630 may be decreased due to the contact layer 730, so that the first and second electrodes 530 and 630 may be uniformly formed.

According to an exemplary embodiment, both of the first and second electrodes 530 and 630 are formed on the second surface 32 of the base substrate 30, and thus, a shadow is not generated that may be generated in cases where an electrode is formed on the first surface 31 onto which sunlight is incident. Thus, a power efficiency of the solar cell 5 may be improved. The contact layer 730 may decrease a contact resistance between the base substrate 30 including the first and second doped patterns 230 and 250 and the first and second electrodes 530 and 630, so that the first and second electrodes 530 and 630 may be uniformly formed.

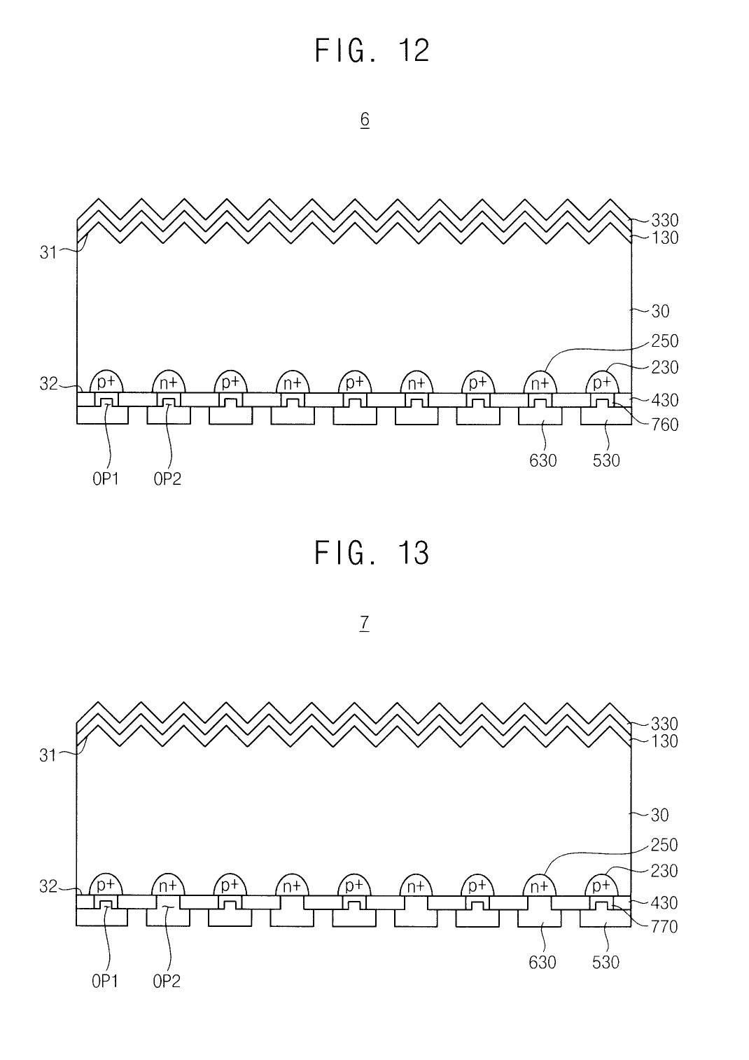

FIG. 12 is a cross-sectional view illustrating a solar cell according to an exemplary embodiment of the present invention.

Referring to FIG. 12, the solar cell 6 according to an exemplary embodiment is substantially the same as the solar cell 5 of FIGS. 9 and 10 except for a contact layer 760. Thus, the same reference numerals are used to denote the same or substantially the same elements as those described in connection with FIGS. 9 and 10.

The solar cell 6 includes a base substrate 30 including a doped layer 130, a first doped pattern 230, and a second doped pattern 250, a first insulating layer 330, a second insulating layer 430, a contact layer 760, a first electrode 530, and a second electrode 630. The first electrode 530 is electrically connected to the first doped pattern 230 and the second electrode 630 is electrically connected to the second doped pattern 250.

The contact layer 760 is formed around the first and second openings OP1 and OP2 exposing the first and second doped patterns 230 and 250, respectively. For example, according to an embodiment, the contact layer 760 may be formed between the first and second doped patterns 230 and 250 and the first and second electrodes 530 and 630, and may cover side surfaces of the second insulating layer 430 and the first and second doped patterns 230 and 250 exposed by the second insulating layer 430.

Although not shown in the figure, the contact layer 760 may have two or more layers. According to an embodiment, the solar cell 6 may further include a passivation layer between the base substrate 30 and the second insulating layer 430.

The method of manufacturing the solar cell 6 according to an exemplary embodiment is substantially the same as the method of manufacturing the solar cell 5 of FIG. 10, except that the contact layer 760 may be formed only around the first and second openings OP1 and OP2. Alternatively, as shown in FIG. 10F, after the contact layer 760 is formed, the contact layer 760 may be removed except for a portion surrounding the first and second openings OP1 and OP2.

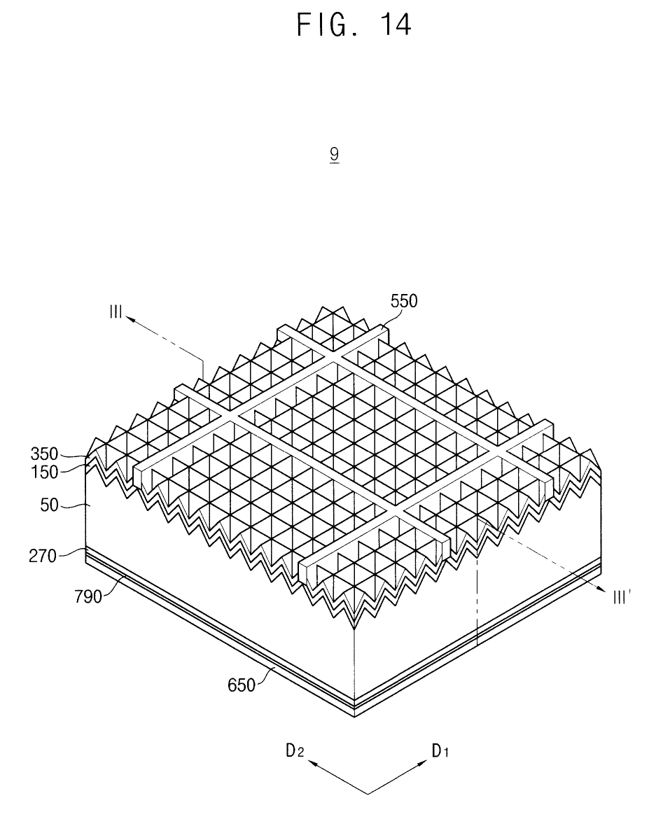

FIG. 13 is a cross-sectional view illustrating a solar cell according to an exemplary embodiment of the present invention.

Referring to FIG. 13, the solar cell 7 according to an exemplary embodiment is substantially the same as the solar cell 5 of FIGS. 9 and 10 except for a contact layer 770. Thus, the same reference numerals are used to denote the same or substantially the same elements as those described in connection with FIGS. 9 and 10.

The solar cell 7 includes a base substrate 30 including a doped layer 130, a first doped pattern 230, and a second doped pattern 250, a first insulating layer 330, a second insulating layer 430, a contact layer 770, a first electrode 530, and a second electrode 630. The first electrode 530 is electrically connected to the first doped pattern 230 and the second electrode 630 is electrically connected to the second doped pattern 250.

The contact layer 770 is formed around the first openings OP1 exposing the first doped pattern 230. For example, according to an embodiment, the contact layer 770 may be formed between the first doped pattern 230 and the first electrode 530, and may cover side surfaces of the second insulating layer 430 and the first doped pattern 230 exposed by the second insulating layer 430.

Although not shown in the figure, the contact layer 770 may have two or more layers. According to an embodiment, the solar cell 7 may further include a passivation layer between the base substrate 30 and the second insulating layer 430.

The method of manufacturing the solar cell 7 according to an exemplary embodiment is substantially the same as the method of manufacturing the solar cell 5 of FIG. 10, except that the contact layer 770 may be formed only around the first openings OP1.

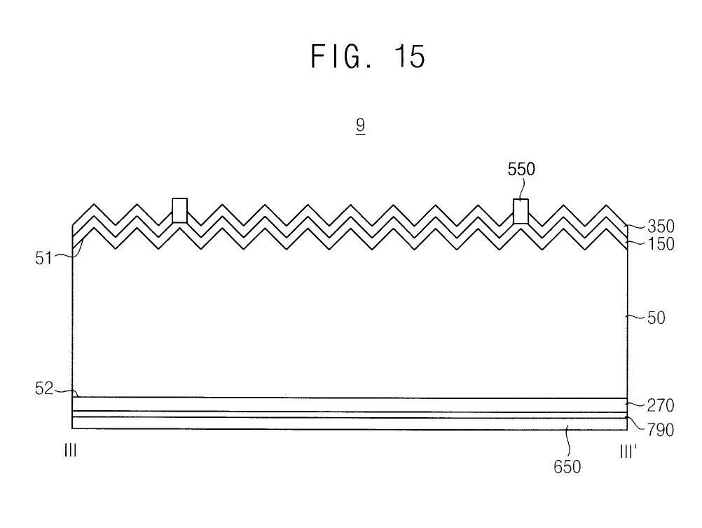

FIG. 14 is a perspective view illustrating a solar cell according to an exemplary embodiment of the present invention. FIG. 15 is a cross-sectional view taken along a line III-III′ of FIG. 14.

Referring to FIGS. 14 and 15, the solar cell 9 according to an exemplary embodiment includes a base substrate 50 including a first doped layer 150 and a second doped layer 270, a first insulating layer 350, a first electrode 550, a contact layer 790, and a second electrode 650.

The base substrate 50 includes a first surface 51 onto which sunlight is incident and a second surface 52 facing the first surface 51. The first surface 51 may include a convex-concave pattern to minimize a reflection of sunlight.

The base substrate 50 may be a p-type silicon substrate. For example, according to an embodiment, the base substrate 50 may include an element in Group IV and an element in Group III. The base substrate 50 may be a single-crystalline, or polycrystalline substrate. According to an exemplary embodiment, the solar cell 9 includes the p-type silicon substrate. Alternatively, an n-type silicon substrate may be used as the base substrate 50 instead of the p-type silicon substrate.

The first doped layer 150 is formed on the first surface 51 of the base substrate 50. The first doped layer 150 may include an n-type semiconductor including a first dopant. The first dopant may include an element in Group V, such as phosphorus (P), arsenic (As), etc.

The second doped layer 270 is entirely formed on the second surface 52 of the base substrate 50. The second doped layer 270 may include a p-type semiconductor including a second dopant. The second dopant may include an element in Group III, such as boron (B), aluminum (Al), gallium (Ga), indium (In), etc.

The first insulating layer 350 is formed on the first doped layer 150. The first insulating layer 350 may be an anti-reflection layer to minimize a reflection of sunlight incident onto the first doped layer 150. The first insulating layer 350 may protect the base substrate 50. The first insulating layer 350 may include silicon nitride (SiNx).

The first electrode 550 is directly connected to the first doped layer 150, so that the first electrode 550 collects the electrons. The first insulating layer 350 is removed at a portion where the first electrode 550 and the first doped layer 150 contact each other. The first electrode 550 may include a conductive metal, such as silver (Ag).

The first electrode 550 may include a plurality of bus lines formed in the first direction D1 and a plurality of finger lines formed in a second direction D2 substantially perpendicular to the first direction D1.

The contact layer 790 is entirely formed on the second doped layer 270. For example, according to an embodiment, a thickness of the contact layer 790 may be in a range of about 300 nm to about 500 nm. Although not shown in the figure, the contact layer 790 may have two or more layers.

The contact layer 790 may be a silicon-germanium (SiGe) thin film doped with a dopant or a silicon (Si) thin film doped with the dopant. The silicon-germanium (SiGe) or silicon (Si) thin film may be an amorphous, single-crystalline, or polycrystalline film. The dopant may include an element in Group III, such as boron (B), aluminum (Al), gallium (Ga), indium (In), etc. Alternatively, the dopant may include an element in Group V, such as phosphorus (P), arsenic (As), etc.

According to an exemplary embodiment, the second doped layer 270 includes the p-type semiconductor, so that the dopant doped into the contact layer 790 may include the second dopant like the second doped layer 270. For example, according to an embodiment, the contact layer 790 may include silicon-germanium (SiGe) doped with boron (B).

Alternatively, the contact layer 790 may include titanium (Ti), aluminum (Al), titanium tungsten (TiW), tungsten silicide, tungsten nitride, titanium nitride, aluminum nitride, tantalum nitride, etc.

The second electrode 650 is formed on the contact layer 790. The second electrode 650 may include a conductive metal, such as aluminum (Al), silver (Ag), titanium (Ti), copper (Cu), tungsten (W), tin (Sn), titanium nitride, etc. For example, according to an embodiment, the second electrode 650 may include aluminum (Al).

The contact layer 790 includes the dopant or a metal element functioning as a conductor, so that the second electrode 650 is electrically connected to the second doped layer 270 through the contact layer 790, respectively.

The contact layer 790 has a superior adhesive strength with the second electrode 650 including the conductive metal and with the base substrate 50 including the silicon because the contact layer 790 includes the conductive metal and the silicon. Therefore, a contact resistance between the base substrate 50 including the second doped layer 270 and the second electrode 650 may be decreased, so that a power efficiency of the solar cell 9 may be improved.

According to the embodiments of the present invention, the solar cell includes the contact layer between the substrate including the doped pattern and the electrode. The contact resistance between the substrate and the electrode may be decreased, so that the doped pattern and the electrode may be uniformly formed. Accordingly, the power efficiency of the solar cell may be improved

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims.

What is claimed is:

1. A solar cell comprising:
a substrate including a first surface onto which sunlight is incident and a second surface opposite to the first surface;
a doped pattern on the second surface of the substrate;
a contact layer on the doped pattern; and
an electrode on the contact layer and electrically connected to the doped pattern.

2. The solar cell of claim 1, wherein the contact layer comprises at least one of silicon-germanium (SiGe) doped with a dopant and silicon (Si) doped with the dopant.

3. The solar cell of claim 2, wherein the dopant comprises at least one selected from the group consisting of boron (B), aluminum (Al), gallium (Ga), indium (In), phosphorus (P), and arsenic (As).

4. The solar cell of claim 2, wherein the contact layer comprises:
a first contact layer doped with the dopant of a first concentration; and
a second contact layer doped with the dopant of a second concentration lower than the first concentration, the second contact layer being formed on the first contact layer.

5. The solar cell of claim 1, wherein the contact layer comprises at least one selected from the group consisting of titanium (Ti), aluminum (Al), titanium tungsten (TiW), tungsten silicide, tungsten nitride, titanium nitride, aluminum nitride, and tantalum nitride.

6. The solar cell of claim 1, wherein the doped pattern is formed on a portion of the second surface,
the solar cell further comprising an insulating layer on the second surface, the insulating layer exposing the doped pattern.

7. The solar cell of claim 6, wherein the contact layer is formed between the doped pattern and the electrode and between the insulating layer and the electrode.

8. The solar cell of claim 6, wherein the contact layer is formed between the doped pattern and the electrode.

9. The solar cell of claim 6, further comprising a passivation layer between the second surface of the substrate and the insulating layer.

10. The solar cell of claim 9, wherein the passivation layer comprises aluminum oxide (Al₂O₃).

11. The solar cell of claim 6, wherein the doped pattern comprises:
a first doped pattern doped with a first dopant; and
a second doped pattern doped with a second dopant.

12. The solar cell of claim 11, wherein the contact layer is formed between the first doped pattern and the electrode, between the second doped pattern and the electrode, and between the insulating layer and the electrode.

13. The solar cell of claim 11, wherein the contact layer is formed between the first doped pattern and the electrode, and between the second doped pattern and the electrode.

14. The solar cell of claim 11, wherein the contact layer is formed between the first doped pattern and the electrode.

15. The solar cell of claim 1, wherein the doped pattern is formed on the entire second surface, and the contact layer is formed on the entire doped pattern.

16. The solar cell of claim 1, wherein the electrode comprises at least one selected from the group consisting of aluminum (Al), silver (Ag), titanium (Ti), copper (Cu), tungsten (W), tin (Sn), and titanium nitride.

17. A method of manufacturing a solar cell, the method comprising:
forming a contact layer on a second surface of a substrate, the substrate including a first surface onto which sunlight is incident and the second surface opposite to the first surface;
forming a conductive metal layer on the contact layer; and
firing the conductive metal layer to form a doped pattern on the second surface of the substrate and to form an electrode on the contact layer.

18. The method of claim 17, wherein the contact layer comprises at least one of silicon-germanium (SiGe) doped with a dopant and silicon (Si) doped with the dopant.

19. The method of claim 18, wherein the dopant comprises at least one selected from the group consisting of boron (B), aluminum (Al), gallium (Ga), indium (In), phosphorus (P), and arsenic (As).

20. The method of claim 17, wherein the contact layer comprises at least one selected from the group consisting of titanium (Ti), aluminum (Al), titanium tungsten (TiW), tungsten silicide, tungsten nitride, titanium nitride, aluminum nitride, and tantalum nitride.

21. The method of claim 17, wherein the contact layer is formed by CVD using a boron trichloride (BCl₃) gas, a germane (GeH₄) gas, and a silane (SiH₄) gas.

22. The method of claim 17, wherein the contact layer is formed by CVD using a first gas composition having a boron trichloride (BCl₃) gas of a first concentration, a germane (GeH₄) gas, and a silane (SiH₄) gas, and a second gas composition having a boron trichloride (BCl₃) gas of a second concentration lower than the first concentration, a germane (GeH₄) gas, and a silane (SiH₄) gas.

23. The method of claim 17, further comprising CVD using a boron trichloride (BCl₃) gas.

24. The method of claim 17, wherein the conductive metal layer comprises at least one selected from the group consisting of aluminum (Al), silver (Ag), titanium (Ti), copper (Cu), tungsten (W), tin (Sn), and titanium nitride.

25. The method of claim 17, wherein the conductive metal layer is formed on the contact layer using a screen printing method.

26. The method of claim 17, further comprising:
forming an insulating layer on the second surface of the substrate; and
patterning the insulating layer to define a diffusion region exposing the second surface.

27. The method of claim 26, further comprising:
forming a passivation layer between the second surface of the substrate and the insulating layer.

28. A method of manufacturing a solar cell, the method comprising:
doping a first dopant and a second dopant on a second surface of a substrate to form a first doped pattern and a second doped pattern, respectively, the substrate including a first surface onto which sunlight is incident and the second surface opposite to the first surface;
forming a contact layer on the first doped pattern; and
forming first and second electrodes electrically connected to the first and second doped patterns, respectively.
